(19) United States
(12) Patent Application Publication
(10) Pub. No.: US 2025/0267998 A1
(43) Pub. Date: Aug. 21, 2025

(54) LIGHT-EMITTING DEVICE AND METHOD OF MANUFACTURING LIGHT-EMITTING DEVICE

(71) Applicant: NICHIA CORPORATION, Anan-shi (JP)

(72) Inventors: Kosuke SATO, Anan-shi (JP); Daisuke SANGA, Tokushima-shi (JP); Hiroki TOMINAGA, Anan-shi (JP)

(73) Assignee: NICHIA CORPORATION, Anan-shi (JP)

(21) Appl. No.: 19/055,496

(22) Filed: Feb. 18, 2025

(30) Foreign Application Priority Data
Feb. 20, 2024 (JP) 2024-023654

(51) Int. Cl. H10H 20/857; H10H 20/01

(52) U.S. Cl. CPC H10H 20/857; H10H 20/0364

(57) ABSTRACT

A light-emitting device includes: a substrate including a base material and a Cu wiring line disposed on an upper surface side of the base material; an insulating layer disposed on the substrate and having an opening on at least a part of an upper surface of the Cu wiring line; a Ti layer covering at least the upper surface of the Cu wiring line; a TiN layer disposed on the Ti layer; a TiW layer disposed on the TiN layer; a metal layer disposed on the TiW layer and containing at least one of Au, Pt, Ru, Pd, or Rh; a conductive member disposed on the metal layer and containing Au; and a light-emitting element including an electrode disposed on the conductive member.

### CROSS-REFERENCE TO RELATED APPLICATIONS

The present application claims priority under 35 U.S.C. § 119 to Japanese Patent Application No. 2024-023654, filed Feb. 20, 2024, the content of which is hereby incorporated by reference in its entirety.

### BACKGROUND

### 1. Technical Field

The present disclosure relates to a light-emitting device and a method of manufacturing the light-emitting device.

### 2. Description of Related Art

Japanese Patent Publication No. 2005-150440 describes a semiconductor device including a semiconductor substrate, a metal pad formed as an electrode of the semiconductor substrate, a barrier metal layer stacked on the metal pad, and a bump formed on the barrier metal layer.

### SUMMARY

When a portion of the barrier metal layer is etched using the bump as a mask subsequent to forming the bump by plating, if the amount of side etching of the barrier metal layer is too large, a space connecting the outside and wiring such as metal pads is formed, increasing the possibility of contact between the wiring and a corrosive substance.

Embodiments of the present disclosure can provide a light-emitting device that suppresses corrosion of wiring lines and a method of manufacturing the light-emitting device.

A light-emitting device according to an embodiment of the present disclosure includes: a substrate including a base material and a Cu wiring line disposed on an upper surface side of the base material; an insulating layer disposed on the substrate and having an opening on at least a part of an upper surface of the Cu wiring line; a Ti layer covering at least the upper surface of the Cu wiring line; a TiN layer disposed on the Ti layer; a TiW layer disposed on the TiN layer; a metal layer disposed on the TiW layer and containing at least one of Au, Pt, Ru, Pd, or Rh; a conductive member disposed on the metal layer and containing Au; and a light-emitting element including an electrode disposed on the conductive member.

A light-emitting device according to an embodiment of the present disclosure includes: a substrate including a base material and a Cu wiring line disposed on an upper surface side of the base material; an insulating layer disposed on the substrate and having an opening on at least a part of an upper surface of the Cu wiring line; a TiW layer covering the upper surface of the Cu wiring line, an inner surface of the insulating layer defining the opening, and a part of an upper surface of the insulating layer continuous with the inner surface; a first Ti layer covering an upper surface of the TiW layer, and covering an outer lateral surface of the TiW layer located between the upper surface of the TiW layer and the upper surface of the insulating layer; a metal layer disposed on the first Ti layer and containing at least one of Au, Pt, Ru, Pd, or Rh; a conductive member disposed on the metal layer and containing Au; and a light-emitting element including an electrode disposed on the conductive member.

A light-emitting device according to an embodiment of the present disclosure includes: a substrate including a base material and a Cu wiring line disposed on an upper surface side of the base material; an insulating layer disposed on the substrate and having an opening on at least a part of an upper surface of the Cu wiring line; a foundation layer covering the upper surface of the Cu wiring line, an inner surface of the insulating layer defining the opening, and a part of an upper surface of the insulating layer continuous with the inner surface; a metal layer disposed on the foundation layer and containing at least one of Au, Pt, Ru, Pd, or Rh; a conductive member disposed on the metal layer and containing Au; and a light-emitting element including an electrode disposed on the conductive member. In the foundation layer, a portion covering a part of the upper surface of the insulating layer includes an outer lateral surface defining an outer edge of the foundation layer, and a recessed portion recessed toward a center of the foundation layer in a top view from at least a part of a region of the outer lateral surface.

A method of manufacturing a light-emitting device according to an embodiment of the present disclosure includes: preparing a substrate including a base material and a Cu wiring line disposed on an upper surface side of the base material; forming an insulating layer on the substrate so that an opening is formed on at least a part of an upper surface of the Cu wiring line; forming a Ti layer so as to cover at least the upper surface of the Cu wiring line; forming a TiN layer on the Ti layer; forming a TiW layer on the TiN layer; forming a metal layer on the TiW layer, the metal layer containing at least one of Au, Pt, Ru, Pd, or Rh; forming a resist layer on at least a part of the insulating layer; disposing a light-emitting element on the resist layer at a position separated from the metal layer; forming a conductive member containing Au on the metal layer by plating and bonding the conductive member and an electrode of the light-emitting element; removing the resist layer; and etching at least a part of the TiW layer that does not overlap the conductive member in a top view.

A method of manufacturing a light-emitting device according to an embodiment includes: preparing a substrate including a base material and a Cu wiring line disposed on an upper surface side of the base material; forming an insulating layer on the substrate so that an opening is formed on at least a part of an upper surface of the Cu wiring line; forming a first TiW layer and a second TiW layer, the first TiW layer being formed to cover each of the upper surface of the Cu wiring line, an inner surface of the insulating layer defining the opening, and a part of the upper surface of the insulating layer continuous with the inner surface, and the second TiW layer being formed on the upper surface of the insulating layer at a position separated from the first TiW layer; forming a first Ti layer so as to cover an upper surface of the first TiW layer and an outer lateral surface of the first TiW layer located between the upper surface of the first TiW layer and the upper surface of the insulating layer; forming a metal layer on the first Ti layer, the metal layer containing at least one of Au, Pt, Ru, Pd, or Rh; forming a resist layer on at least a part of the insulating layer; disposing a light-emitting element on the resist layer at a position separated from the metal layer; forming a conductive member containing Au on the metal layer by plating and bonding the conductive member and an electrode of the light-emitting element; removing the resist layer; and etching the second TiW layer.

A method of manufacturing a light-emitting device according to an embodiment includes: preparing a substrate including a base material and a Cu wiring line disposed on an upper surface side of the base material; forming an insulating layer on the substrate so that an opening is formed on at least a part of an upper surface of the Cu wiring line; forming a first foundation layer and a second foundation layer, the first foundation layer being formed to cover each of the upper surface of the Cu wiring line, an inner surface of the insulating layer defining the opening, and a part of an upper surface of the insulating layer continuous with the inner surface, and the second foundation layer being formed on the upper surface of the insulating layer at a position separated from the first foundation layer; forming a metal layer on at least the first foundation layer, the metal layer containing at least one of Au, Pt, Ru, Pd, or Rh; forming a resist layer on at least a part of the insulating layer; disposing a light-emitting element on the resist layer at a position separated from the metal layer; forming a conductive member containing Au on the metal layer by plating and bonding the conductive member and an electrode of the light-emitting element; removing the resist layer; and etching the second foundation layer.

According to an embodiment of the present disclosure, a light-emitting device that suppresses corrosion of wiring lines and a method of manufacturing the light-emitting device can be provided.

### BRIEF DESCRIPTION OF THE DRAWINGS

A more complete appreciation of embodiments of the invention and many of the attendant advantages thereof will be readily obtained by reference to the following detailed description when considered in connection with the accompanying drawings.

FIG. 1 is a schematic perspective view of a light-emitting device according to a first embodiment.

FIG. 2 is an enlarged top view schematically illustrating region II illustrated in FIG. 1 in the light-emitting device according to the first embodiment.

FIG. 3 is an enlarged schematic top view for describing a configuration example of a unit region III illustrated in FIG. 2 in the light-emitting device according to the first embodiment.

FIG. 4 is a schematic cross-sectional view illustrating a cross section taken along line IV-IV illustrated in FIG. 3 in the light-emitting device according to the first embodiment.

FIG. 5A is a schematic top view for describing an example of a method of manufacturing the light-emitting device according to the first embodiment.

FIG. 5B is a schematic cross-sectional view for describing the example of the method of manufacturing the light-emitting device according to the first embodiment.

FIG. 6A is a schematic top view for describing an example of the method of manufacturing the light-emitting device according to the first embodiment.

FIG. 6B is a schematic cross-sectional view for describing the example of the method of manufacturing the light-emitting device according to the first embodiment.

FIG. 7A is a schematic top view for describing an example of the method of manufacturing the light-emitting device according to the first embodiment.

FIG. 7B is a schematic cross-sectional view for describing the example of the method of manufacturing the light-emitting device according to the first embodiment.

FIG. 8A is a schematic top view for describing an example of the method of manufacturing the light-emitting device according to the first embodiment.

FIG. 8B is a schematic cross-sectional view for describing the example of the method of manufacturing the light-emitting device according to the first embodiment.

FIG. 9A is a schematic top view for describing an example of a method of manufacturing the light-emitting device according to the first embodiment.

FIG. 9B is a schematic cross-sectional view for describing the example of the method of manufacturing the light-emitting device according to the first embodiment.

FIG. 10A is a schematic top view for describing an example of the method of manufacturing the light-emitting device according to the first embodiment.

FIG. 10B is a schematic cross-sectional view for describing the example of the method of manufacturing the light-emitting device according to the first embodiment.

FIG. 11A is a schematic top view for describing an example of the method of manufacturing the light-emitting device according to the first embodiment.

FIG. 11B is a schematic cross-sectional view for describing the example of the method of manufacturing the light-emitting device according to the first embodiment.

FIG. 12A is a schematic top view for describing an example of the method of manufacturing the light-emitting device according to the first embodiment.

FIG. 12B is a schematic cross-sectional view for describing the example of the method of manufacturing the light-emitting device according to the first embodiment.

FIG. 13A is a schematic top view for describing an example of the method of manufacturing the light-emitting device according to the first embodiment.

FIG. 13B is a schematic cross-sectional view for describing the example of the method of manufacturing the light-emitting device according to the first embodiment.

FIG. 14 is an enlarged schematic top view for describing a configuration example of a unit region III in a light-emitting device according to a second embodiment.

FIG. 15 is a schematic cross-sectional view illustrating a cross section taken along line XV-XV illustrated in FIG. 14 in the light-emitting device according to the second embodiment.

FIG. 16 is a schematic cross-sectional view illustrating a cross section taken along line XVI-XVI illustrated in FIG. 14 in the light-emitting device according to the second embodiment.

FIG. 17A is a schematic top view for describing an example of an example of a method of manufacturing the light-emitting device according to the second embodiment.

FIG. 17B is a schematic cross-sectional view for describing the example of the method of manufacturing the light-emitting device according to the second embodiment.

FIG. 18A is a schematic top view for describing an example of the method of manufacturing the light-emitting device according to the second embodiment.

FIG. 18B is a schematic cross-sectional view for describing the example of the method of manufacturing the light-emitting device according to the second embodiment.

FIG. 19A is a schematic top view for describing an example of the method of manufacturing the light-emitting device according to the second embodiment.

FIG. 19B is a schematic cross-sectional view for describing the example of the method of manufacturing the light-emitting device according to the second embodiment.

FIG. 19C is a schematic cross-sectional view for describing the example of the method of manufacturing the light-emitting device according to the second embodiment.

### DETAILED DESCRIPTION OF EMBODIMENT

A light-emitting device and a method of manufacturing the light-emitting device according to embodiments of the present disclosure will be described below with reference to the drawings. The following forms are examples of the light-emitting device and the method of manufacturing the light-emitting device for realizing the technical concept of the embodiments, and are not limited to the following. The dimensions, materials, shapes, relative arrangements, and the like of the components described in the embodiments are not intended to limit the scope of the present disclosure, but are merely illustrative examples, unless otherwise specifically stated. Note that the sizes, positional relationship, or the like of members illustrated in each of the drawings may be exaggerated for clarity of description. In the following description, members having the same terms and reference signs represent the same members or members of the same quality, and detailed description of these members is omitted as appropriate. As a cross-sectional view, an end view illustrating only a cut surface may be used.

In the following drawings, directions may be indicated by an X axis, a Y axis, and a Z axis. The X axis, the Y axis, and the Z axis are orthogonal to one another. The direction in which the arrow points in the X axis direction is denoted as +X direction or +X side, and the opposite direction of the +X direction is denoted as −X direction or −X side. The direction in which the arrow points in the Y axis direction is denoted as +Y direction or +Y side, and the opposite direction of the +Y direction is denoted as −Y direction or −Y side. The direction in which the arrow points in the Z axis direction is denoted as +Z direction or +Z side, and the opposite direction of the +Z direction is denoted as −Z direction or −Z side. Also, the expression “in top view” used in the embodiments refers to viewing an object from the +Z direction. However, this does not limit the orientation of the light-emitting device during use, and the orientation of the light-emitting device may be any chosen orientation. In the embodiments, a surface of a target object when viewed from the +Z direction is referred to as an “upper surface”, and a surface of the target object when viewed from the −Z direction is referred to as a “lower surface”. In the following embodiments, “being aligned with the X axis, the Y axis, and the Z axis” includes an object having an inclination within a range of ±10° relative to the axes. In the embodiments, the orthogonality may include an error within ±10° with respect to 90°.

In the present disclosure, a polygon such as a rectangle will be referred to as a polygon, including a shape with rounded, chamfered, angled, rounded, or otherwise processed corners of a polygon, unless otherwise specified. A shape obtained by processing not only the corners (ends of a side) but also an intermediate portion of the side is similarly referred to as a polygon. That is, a shape that is partially processed while leaving the polygon as the base is included in the interpretation of the “polygon” described in the present disclosure.

The same applies not only to polygons but also to the terms representing specific shapes such as trapezoids, circles, protrusions, and recessions. The same also applies to the terms related to each side forming the shape. That is, even when processing is performed on a corner or an intermediate portion of a certain side, the interpretation of “side” includes the processed portion.

The term “to cover” or “covering” is not limited to cases of direct contact, but also includes cases of indirect covering, e.g., through other members. The term “to dispose” is not limited to cases of direct contact, but also includes cases of indirect disposing, e.g., through other members.

### First Embodiment

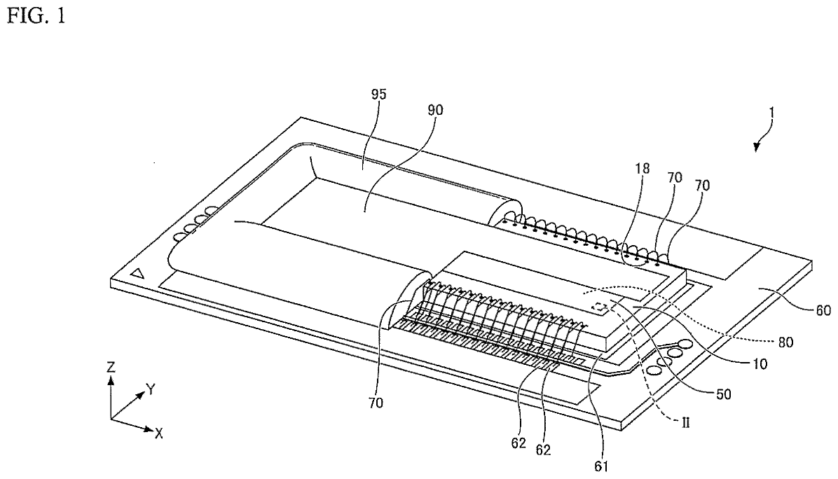

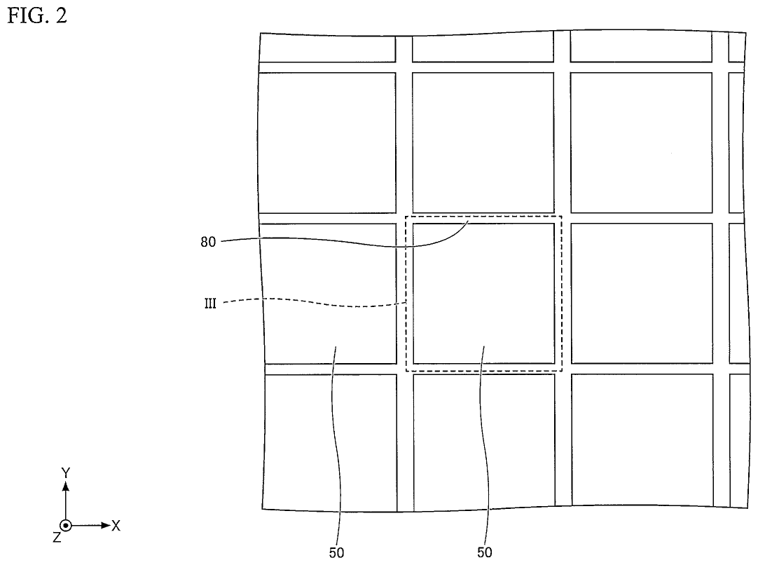

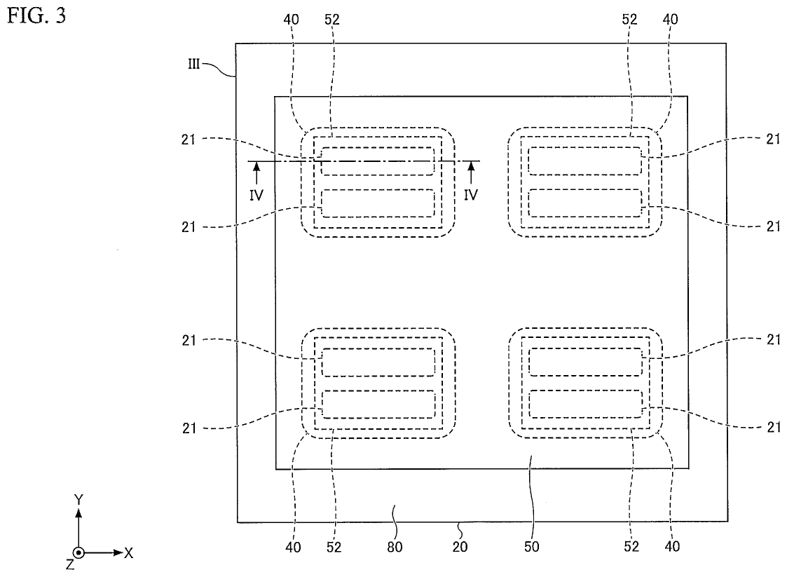

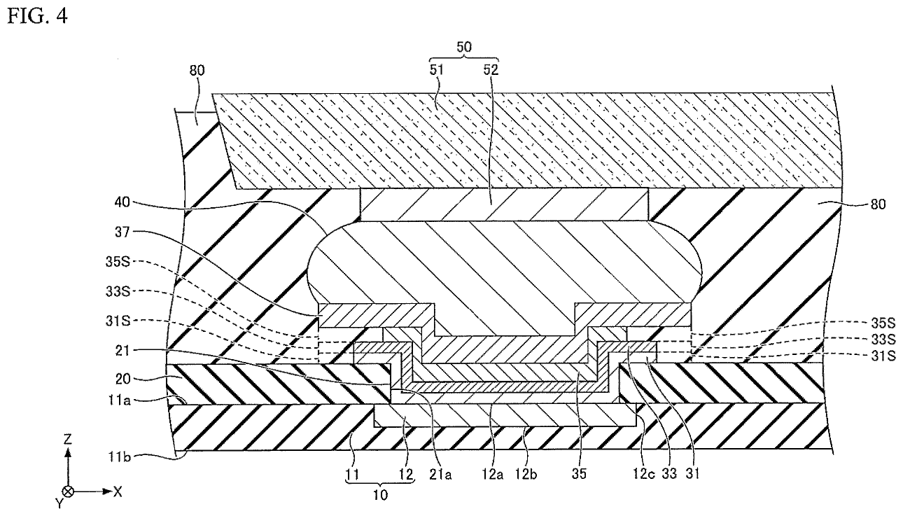

A configuration example of a light-emitting device 1 according to a first embodiment will be described with reference to FIGS. 1 to 4. FIG. 1 is a perspective view schematically illustrating the light-emitting device 1 according to the first embodiment. FIG. 2 is an enlarged top view schematically illustrating region II illustrated in FIG. 1 in the light-emitting device 1 according to the first embodiment. FIG. 3 is an enlarged schematic top view illustrating a configuration example in the unit region III illustrated in FIG. 2. FIG. 4 is a cross-sectional view schematically illustrating a cross section taken along line IV-IV illustrated in FIG. 3.

### Overall Configuration of Light-Emitting Device 1

The light-emitting device 1 includes a substrate 10, an insulating layer 20, a titanium (Ti) layer 31, a titanium nitride (TiN) layer 33, a titanium-tungsten (TiW) layer 35, a metal layer 37, a conductive member 40, and a light-emitting element 50. The light-emitting device 1 can further include a package substrate 60, a wire line 70, a light shielding member 80, a wavelength conversion member 90, and a covering member 95. In FIG. 1, a part of the wavelength conversion member 90 and a part of the covering member 95 are omitted for convenience of description. In FIG. 1, the light-emitting element 50 covered with the part of the wavelength conversion member 90 which is omitted from the drawing, and the wire line 70 covered with the part of the covering member 95 which is omitted from the drawing are visible.

As illustrated in FIG. 1, the package substrate 60 includes a heat dissipation portion 61 and a plurality of terminals 62 individually arranged in a region on an upper surface of the package substrate 60, the region sandwiching the heat dissipation portion 61. The substrate 10 is, for example, supported by the package substrate 60 via the heat dissipation portion 61. Terminals 18 disposed on the upper surface of the substrate 10 are electrically connected to the terminals 62 of the package substrate 60 via the wire lines 70. The terminals 62 of the package substrate 60 are electrically connected to an external power supply. That is, the terminals 18 of the substrate 10 are electrically connected to an external power supply via the terminals 62 of the package substrate 60 and the wire lines 70. The terminals 18 disposed on the upper surface of the substrate 10, the terminals 62 disposed on the upper surface of the package substrate 60, and the wire lines 70 are covered with the covering member 95.

The wavelength conversion member 90 is disposed on the light-emitting element 50. The wavelength conversion member 90 includes, for example, a base material made of a light-transmissive resin and a phosphor contained in the base material. The wavelength conversion member 90 converts a part of the wavelength of light emitted from the light-emitting element 50 to light with other wavelengths. This allows extraction of light of predetermined colors, such as blue light, green light, red light, and white light from the light-emitting device 1.

The light-emitting device 1 includes a plurality of the light-emitting elements 50. As illustrated in FIG. 2, the plurality of light-emitting elements 50 are arrayed on the substrate 10 along the X axis direction and the Y axis direction. For example, the light shielding member 80 is disposed between lateral surfaces of adjacent light-emitting elements 50 facing each other, and is also disposed between the substrate 10 and the plurality of light-emitting elements 50. As illustrated in FIG. 2, in a top view, a virtual rectangular region surrounding a single light-emitting element 50 is referred to as a “unit region III”. Adjacent light-emitting elements 50 are surrounded by adjacent unit regions III. That is, the plurality of unit regions III are arrayed along the X axis direction and the Y axis direction, similarly to the plurality of light-emitting elements 50.

FIG. 3 illustrates, in a perspective manner, an electrode 52, an opening 21 of the insulating layer 20, and the conductive member 40 of the light-emitting element 50 surrounded by the unit region III. Here, the insulating layer 20 is a layer located on the −Z side of the light-emitting element 50 and disposed on the substrate 10.

In the example illustrated in FIG. 3, four electrodes 52 are disposed in the unit region III. That is, in the example illustrated in FIG. 3, a single light-emitting element 50 includes four electrodes 52. Among the four electrodes 52, two electrodes 52 located on the-X side correspond to one of n-side electrodes or p-side electrodes. Among the four electrodes 52, two electrodes 52 located on the +X side correspond to the other of the n-side electrodes and the p-side electrodes. However, the number of electrodes 52 included in the single light-emitting element 50 is not limited thereto. The single light-emitting element 50 needs to include at least two electrodes 52.

In a top view, the opening 21 is provided in a region overlapping the electrode 52. In the example illustrated in FIG. 3, two openings 21 each overlap a corresponding electrode 52 in a top view. That is, eight openings 21 are provided in the unit region III. However, the number of the openings 21 is not limited thereto.

In a top view, the conductive member 40 overlaps the electrode 52. The number of conductive members 40 is preferably a number corresponding to the number of electrodes 52. In the example illustrated in FIG. 3, four conductive members 40 are provided in the unit region III. However, the number of the conductive members 40 is not limited thereto. As will be described later with reference to FIG. 4, the Ti layer 31, the TiN layer 33, the TiW layer 35, and the metal layer 37 are disposed on the −Z side of each conductive member 40.

### Substrate 10

As illustrated in FIG. 1, the substrate 10 has a substantially rectangular external shape in a top view. However, the substrate 10 can have another external shape such as a substantially circular shape, a substantially elliptical shape, or a substantially polygonal shape in a top view. The substrate 10 can include an integrated circuit for controlling a light emitting operation of the light-emitting element 50. An example of the integrated circuit is an electronic circuit such as an application specific integrated circuit (ASIC). The integrated circuit is used to control the light emitting operation of each of the plurality of light-emitting elements 50.

As illustrated in FIG. 4, the substrate 10 includes a base material 11 and a copper (Cu) wiring line 12. The Cu wiring line 12 is, for example, electrically connected to the terminal 18 via an internal wiring line provided inside the base material 11. At least two Cu wiring lines 12 are provided in the unit region III. The two Cu wiring lines 12 are arranged at positions separated from each other. However, the number of the Cu wiring lines 12 is not limited thereto.

The base material 11 is a base material of the substrate 10. As illustrated in FIG. 4, the base material 11 has an upper surface 11a, a lower surface 11b, and a lateral surface between the upper surface 11a and the lower surface 11b. The base material 11 is mainly made of an insulator having insulating properties, or a semiconductor substance. Examples of the substance constituting the base material 11 include a semiconductor substrate such as silicon, a ceramic substrate such as aluminum nitride, and a resin substrate such as glass epoxy. However, the substance constituting the base material 11 is not limited thereto.

The Cu wiring line 12 has a substantially rectangular external shape in a top view. However, the Cu wiring line 12 can have another external shape such as a substantially circular shape, a substantially elliptical shape, or a substantially polygonal shape in a top view. The Cu wiring line 12 is disposed on the upper surface 11a side of the base material 11.

The Cu wiring line 12 has an upper surface 12a, a lower surface 12b, and a lateral surface 12c between the upper surface 12a and the lower surface 12b. The upper surface 12a of the Cu wiring line 12 is exposed from the upper surface 11a of the base material 11. The lower surface 12b and the lateral surface 12c of the Cu wiring line 12 are located inside the base material 11.

### Insulating Layer 20

As illustrated in FIG. 4, the insulating layer 20 is disposed on the base material 11 and the Cu wiring line 12. As described with reference to FIG. 3, the insulating layer 20 includes the opening 21. The opening 21 penetrates through the insulating layer 20 in the Z axis direction. Preferably, the opening 21 is located on the upper surface 12a of the Cu wiring line 12, the upper surface 11a of the base material 11 is covered with the insulating layer 20, and the base material 11 is not exposed from the opening 21 in a top view. Preferably, only the Cu wiring line 12 is exposed from the opening 21, and the interface between the Cu wiring line 12 and the upper surface 11a of the base material 11 is not exposed from the opening 21. This reduces the possibility of the Cu wiring line 12 coming into contact with corrosive substances such as sulfur and sulfur compounds.

Examples of the material constituting the insulating layer 20 include oxides such as silicon oxide (SiO₂), aluminum oxide (Al₂O₃), niobium oxide (Nb₂O₅), and titanium oxide, and nitrides such as silicon nitride (Si₃N₄) and aluminum nitride (AlN). However, the substance constituting the insulating layer 20 is not limited thereto.

### Ti Layer 31

The Ti layer 31 is a layer made of titanium. The Ti layer 31 covers at least the upper surface 12a of the Cu wiring line 12. More specifically, the Ti layer 31 covers a region overlapping the opening 21 in a top view on the upper surface 12a of the Cu wiring line 12. The Ti layer 31 can also cover the inner surface 21a of the insulating layer 20 that defines the opening 21. The Ti layer 31 can also cover a part of the upper surface of the insulating layer 20 continuous with the inner surface 21a. In a top view, the outer edge of the Ti layer 31 is located outside the outer edge of the opening 21. This allows the Ti layer 31 to cover the region overlapping the opening 21 in a top view on the upper surface 12a of the Cu wiring line 12. As a result, formation of the path connecting the outside and the Cu wiring line 12 can be suppressed. This reduces the possibility of the Cu wiring line 12 coming into contact with corrosive substances such as sulfur and sulfur compounds. That is, corrosion such as sulfurization in the Cu wiring line 12 can be suppressed.

In addition, for example, the Ti layer 31 having high adhesion to metals, oxides, and nitrides is in contact with each of the upper surface 12a of the Cu wiring line 12, the inner surface 21a of the insulating layer 20, and a part of the upper surface of the insulating layer 20 continuous with the inner surface 21a, which makes it possible to suppress peeling of the Ti layer 31. The Ti layer 31 also has high adhesion to the TIN layer 33. Therefore, disposing the TiN layer 33 on the Cu wiring line 12 via the Ti layer 31 can suppress separation of the TiN layer 33 from the Cu wiring line 12. A thickness of the Ti layer 31 is preferably in a range from 30 nm to 2500 nm, for example. However, the thickness of the Ti layer 31 is not limited thereto.

In a top view, the outer edge of the Ti layer 31 is preferably located closer to the center of the metal layer 37 than the outer edge of the metal layer 37 is. This allows formation of a recessed space 31S which is, for example, recessed in the X axis direction below the metal layer 37. As illustrated in FIG. 4, a part of the light shielding member 80 is located in the recessed space 31S. That is, a part of the light shielding member 80 located in the recessed space 31S faces the lower surface of the metal layer 37 in the Z axis direction. Therefore, even when a force acting upward on the light shielding member 80 is generated, separation of the light shielding member 80 from the substrate 10 can be suppressed.

### TiN Layer 33

The TiN layer 33 is a layer containing titanium and nitrogen as main components thereof. The composition ratio of titanium and nitrogen in the TiN layer 33 is not limited. The TiN layer 33 can contain an element other than titanium and nitrogen. The TiN layer 33 is disposed on the Ti layer 31. The TiN layer 33 can cover the entire upper surface of the Ti layer 31, or can cover a part of the upper surface of the Ti layer 31. However, the TiN layer 33 preferably covers at least a region of the Ti layer 31 overlapping the upper surface 12a of the Cu wiring line 12 in a top view. Thus, the region of the upper surface 12a of the Cu wiring line 12 overlapping the opening 21 in a top view can be covered with the Ti layer 31 and the TiN layer 33. As a result, formation of the path connecting the outside and the Cu wiring line 12 can be further suppressed. This further suppresses corrosion of the Cu wiring line 12.

In a top view, the outer edge of the TiN layer 33 is preferably located closer to the center of the metal layer 37 than the outer edge of the metal layer 37 is. Thus, for example, a recessed space 33S recessed in the X axis direction can be provided below the metal layer 37. The recessed space 33S can be continuous with the recessed space 31S outside the outer edge of the Ti layer 31. As illustrated in FIG. 4, a part of the light shielding member 80 is located in the recessed space 33S. That is, a part of the light shielding member 80 located in the recessed space 33S faces the lower surface of the metal layer 37 in the Z axis direction. Therefore, even when a force acting upward on the light shielding member 80 is generated, separation of the light shielding member 80 from the substrate 10 can be suppressed.

The thickness of the TiN layer 33 is preferably smaller than the thickness of the TiW layer 35 located on the TiN layer 33. The thickness of the TiN layer 33 is smaller than the thickness of the TiW layer 35, allowing the present invention to be made thinner. The thickness of the TiN layer 33 is preferably in a range from 50 nm to 200 nm, for example. However, the thickness of the TiN layer 33 is not limited thereto.

### TiW Layer 35

The TiW layer 35 is a layer containing titanium and tungsten as main components thereof. The composition ratio of titanium and tungsten in the TiW layer 35 is not limited. The TiW layer 35 can contain an element other than titanium and tungsten. The TiW layer 35 is disposed on the TiN layer 33. The TiW layer 35 can cover the entire upper surface of the TiN layer 33, or can cover a part of the upper surface of the TiN layer 33. The TiW layer 35 can function as a seed layer for growing the conductive member 40.

In a top view, the outer edge of the TiW layer 35 is preferably located closer to the center of the metal layer 37 than the outer edge of the metal layer 37 is. This allows formation of a recessed space 35S which is, for example, recessed in the X axis direction below the metal layer 37. The recessed space 35S can be continuous with the recessed space 33S outside the outer edge of the TiN layer 33. As illustrated in FIG. 4, a part of the light shielding member 80 is located in the recessed space 35S. That is, a part of the light shielding member 80 located in the recessed space 35S faces the lower surface of the metal layer 37 in the Z axis direction. Therefore, even when a force acting upward on the light shielding member 80 is generated, separation of the light shielding member 80 from the substrate 10 can be suppressed.

The thickness of the TiW layer 35 can be smaller than the thickness of the metal layer 37. The thickness of the TiW layer 35 is smaller than the thickness of the metal layer 37, allowing the present invention to be made thinner. In contrast, the thickness of the metal layer 37 can be greater than the thickness of the TiW layer 35 to increase the electrical conductivity. On the other hand, when the TiW layer 35 is thinner than the metal layer 37, the thickness of the TiW layer 35 is preferably in a range from 100 nm to 300 nm, for example. However, the thickness of the TiW layer 35 is not limited thereto.

### Metal Layer 37

The metal layer 37 is disposed on the TiW layer 35. The metal layer 37 contains at least one of gold (Au), platinum (Pt), ruthenium (Ru), palladium (Pd), or rhodium (Rh). The metal layer 37 can have a single-layer structure composed of one kind of metal layer among these metal layers, or can have a laminated structure in which different kinds of metal layers among these metal layers are laminated. This increases the reliability of the metal layer 37. The reflectance of the metal layer 37 can be increased. The thickness of the metal layer 37 is preferably in a range from 150 nm to 800 nm, for example. However, the thickness of the metal layer 37 is not limited thereto.

The metal layer 37 can function as a seed layer for growing the conductive member 40. Since the conductive member 40 contains Au, a layer containing Au is preferable as the metal layer 37. The metal layer 37 is more preferably a layer composed of Au alone from the viewpoint of corrosion resistance and the like. However, the configuration of the metal layer 37 is not limited thereto.

### Conductive Member 40

The conductive member 40 is disposed on the metal layer 37. The conductive member 40 is bonded to the electrode 52 of the light-emitting element 50. The conductive member 40 can function as a bonding member between the substrate 10 and the light-emitting element 50. Preferably, the thickness of the conductive member 40 is, for example, in a range from 2500 nm to 5000 nm. However, the thickness of the conductive member 40 is not limited thereto.

The conductive member 40 contains Au. Alternatively, the conductive member 40 can be made of Au alone. The conductive member 40 containing Au can reduce the electrical resistance in the current path between the Cu wiring line 12 and the electrode 52, while suppressing corrosion of the conductive member 40. In particular, the corrosion resistance can be improved when compared with a conductive member containing Cu having high reactivity with corrosive substances such as sulfur and a sulfur compound.

### Light-Emitting Element 50

The light-emitting element 50 is a semiconductor light-emitting element such as a light emitting diode (LED) or a laser diode (LD). The light-emitting element 50 includes a semiconductor structure 51 and a plurality of electrodes 52. The semiconductor structure 51 includes an n-type semiconductor layer, an active layer, and a p-type semiconductor layer which are stacked in this order in the Z direction. The plurality of electrodes 52 includes an n-side electrode and a p-side electrode. The n-side electrode of the plurality of electrodes 52 is electrically connected to the n-type semiconductor layer of the semiconductor structure 51. On the other hand, the p-side electrode of the plurality of electrodes 52 is electrically connected to the p-type semiconductor layer of the semiconductor structure 51.

For example, the semiconductor structure 51 emits blue light. The n-type semiconductor layer, the active layer, and the p-type semiconductor layer in the semiconductor structure 51 are made of, for example, a nitride-based semiconductor (InₓAl_{y}Ga_{1-X-Y}N, 0≤X, 0≤Y, X+Y≤1). The upper surface of the semiconductor structure 51 corresponds to a light extraction surface.

The semiconductor structure 51 has a substantially rectangular external shape in a top view. However, the semiconductor structure 51 can have another external shape such as a substantially circular shape, a substantially elliptical shape, or a substantially polygonal shape in a top view. The semiconductor structure 51 has an upper surface, a lower surface, and a lateral surface between the upper surface and the lower surface. For example, a protective film made of an insulator material can be disposed on the upper surface and the lateral surface of the semiconductor structure 51. The lateral surface of the semiconductor structure 51 is covered with the light shielding member 80. The plurality of electrodes 52 are disposed on the lower surface of the semiconductor structure 51. The plurality of electrodes 52 are disposed at positions separated from each other on the lower surface of the semiconductor structure 51. The electrode 52 contains, for example, a metal such as Au.

The electrode 52 has a substantially rectangular external shape in a top view. However, the electrode 52 can have another external shape such as a substantially circular shape, a substantially elliptical shape, or a substantially polygonal shape in a top view. The electrode 52 is disposed on the conductive member 40.

### Light Shielding Member 80

The light shielding member 80 preferably has light reflectivity. The light shielding member 80 having the light reflectivity allows the light emitted from the light-emitting element 50 and reaching the light shielding member 80 to be reflected to, for example, the +Z side. Thus, the light-extracting efficiency of the light-emitting device 1 can be improved.

For example, the light shielding member 80 is made of a resin material containing a light reflective material. Examples of the light reflective material include titanium oxide, zinc oxide, magnesium oxide, magnesium carbonate, magnesium hydroxide, calcium carbonate, calcium hydroxide, calcium silicate, magnesium silicate, barium titanate, barium sulfate, aluminum hydroxide, aluminum oxide, zirconium oxide, and silicon oxide. One of these is preferably used alone, or a combination of two or more types thereof are preferably used. Examples of the resin material include a resin material whose main component is a thermosetting resin such as an epoxy resin, an epoxy-modified resin, a silicone resin, a silicone-modified resin, and a phenol resin.

### Method of Manufacturing Light-Emitting Device 1

A method of manufacturing the light-emitting device 1 according to the first embodiment is described below. The method of manufacturing the light-emitting device 1 according to the first embodiment includes preparing the substrate 10, forming the insulating layer 20, forming the Ti layer 31, forming the TiN layer 33, forming the TiW layer 35, forming the metal layer 37, forming the resist layer 55, disposing the light-emitting element 50, bonding the conductive member 40 and the electrode 52 of the light-emitting element 50, removing the resist layer 55, and etching at least a part of the TiW layer 35. For convenience of explanation, the method of manufacturing the light-emitting device 1 according to the first embodiment is described using an example form in the region corresponding to a particular unit region III described with reference to FIG. 3, but the same applies to other unit regions III.

### Preparing Substrate 10

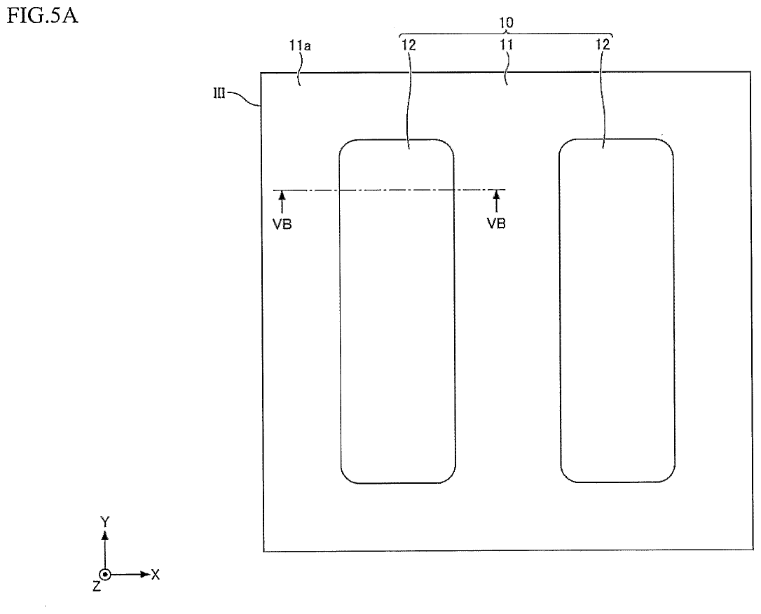

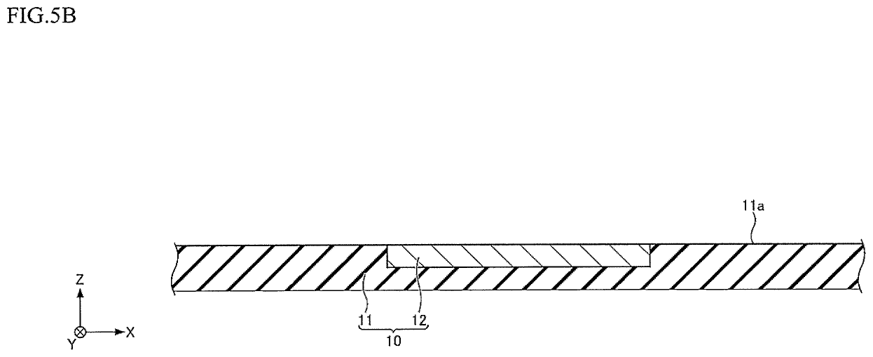

Preparing the substrate 10 is described with reference to FIGS. 5A and 5B. FIG. 5A schematically illustrates a top view of the region of the upper surface corresponding to the unit region III of the substrate 10. FIG. 5B schematically illustrates a cross section taken along line VB-VB illustrated in FIG. 5A. As illustrated in FIGS. 5A and 5B, the prepared substrate 10 includes the base material 11 and the Cu wiring line 12 disposed on the upper surface 11a side of the base material 11. A plurality of recessed portions is formed on the upper surface 11a of the base material 11, and the Cu wiring line 12 is disposed in each recessed portion. Subsequent to disposing Cu in the recessed portion of the upper surface 11a of the base material 11, the surface can be planarized by polishing, grinding, or the like and used as the Cu wiring line 12.

### Forming Insulating Layer 20

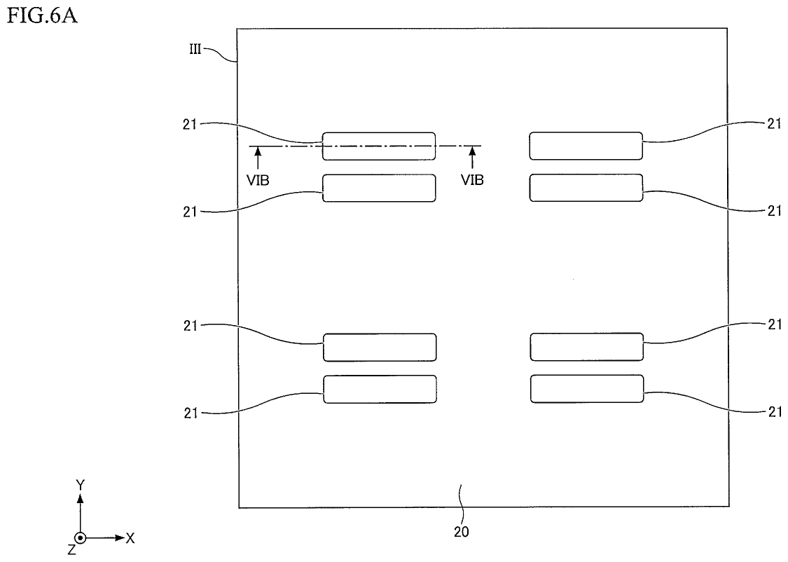

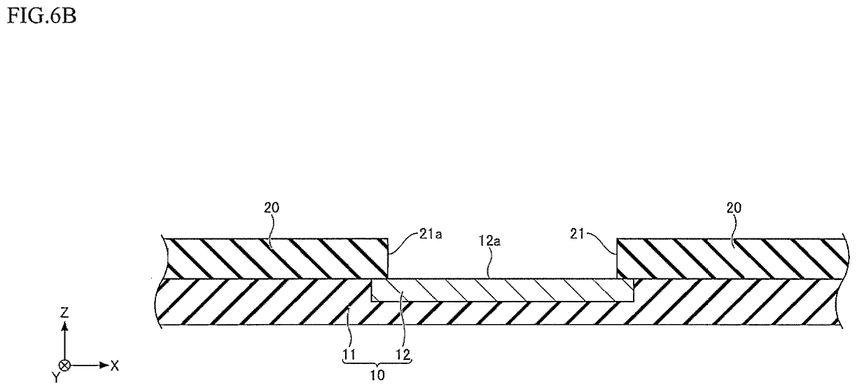

Subsequently, the insulating layer 20 is formed. Forming the insulating layer 20 is described with reference to FIGS. 6A and 6B. FIG. 6A schematically illustrates the upper surface of the region corresponding to the unit region III in an intermediate including the substrate 10 and the insulating layer 20. FIG. 6B schematically illustrates a cross section taken along line VIB-VIB illustrated in FIG. 6A.

As illustrated in FIGS. 6A and 6B, the insulating layer 20 is formed on the substrate 10. Examples of the method of forming the insulating layer 20 include chemical vapor deposition (CVD), sputtering, and the like. At this time, the insulating layer 20 is formed so that the opening 21 is disposed on at least a part of the upper surface 12a of the Cu wiring line 12. For example, by disposing a mask in a region corresponding to the opening 21 and forming the insulating layer 20 in a region other than the mask is disposed on the substrate 10, the opening 21 can be formed on at least a part of the upper surface 12a of the Cu wiring line 12. The opening 21 can also be formed on at least a part of the upper surface 12a of the Cu wiring line 12 by, for example, removing the region corresponding to the opening 21 subsequent to forming the insulating layer 20 uniformly on the substrate 10. Preferably, only the Cu wiring line 12 is exposed from the opening 21 and the interface between the Cu wiring line 12 and the base material 11 is not exposed from the opening 21. This is because the interface between the Cu wiring line 12 and the base material 11 is covered with the insulating layer 20, which suppresses penetration of corrosive substances such as moisture, sulfur and sulfur compounds, and oxygen into the lateral and bottom surfaces of the Cu wiring line 12.

### Forming Ti Layer 31

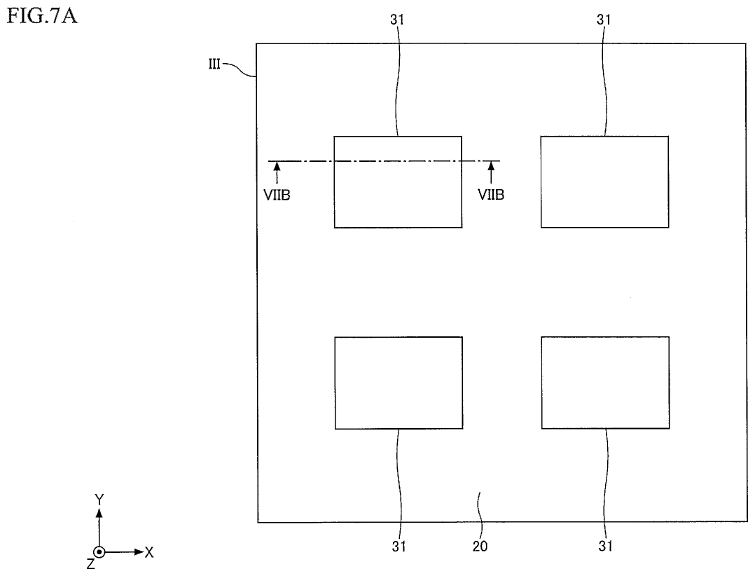

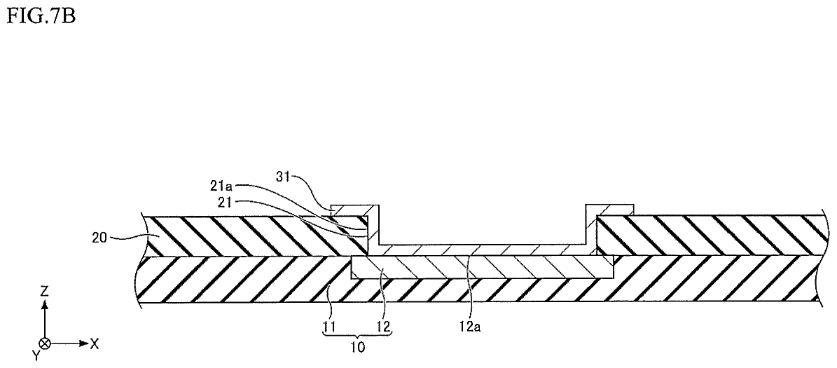

Subsequently, the Ti layer 31 is formed. Forming the Ti layer 31 is described with reference to FIGS. 7A and 7B. FIG. 7A schematically illustrates the upper surface of the region corresponding to the unit region III in the intermediate including the substrate 10, the insulating layer 20, and the Ti layer 31. FIG. 7B schematically illustrates a cross section taken along line VIIB-VIIB illustrated in FIG. 7A.

As illustrated in FIGS. 7A and 7B, the Ti layer 31 is formed so as to cover the upper surface 12a of the Cu wiring line 12. That is, the region of the upper surface 12a of the Cu wiring line 12 overlapping the opening 21 in a top view is covered with the Ti layer 31. This allows the upper surface 12a of the Cu wiring line 12 to be covered with the insulating layer 20 or the Ti layer 31. The Ti layer 31 can be formed so as to cover the inner surface 21a of the insulating layer 20 defining the opening 21. Furthermore, the Ti layer 31 can be formed so as to cover a part of the upper surface of the insulating layer 20 continuous with the inner surface 21a. Examples of the method of forming the Ti layer 31 include sputtering, vacuum deposition, the CVD, atomic layer deposition (ALD), and the like. At this time, the Ti layer 31 preferably covers not only the exposed Cu wiring line 12 but also a part of the insulating layer 20 on the outer periphery of the exposed Cu wiring line 12. This allows the Ti layer 31 to completely cover the Cu wiring line 12 exposed from the insulating layer 20. In particular, the corrosion of the Cu wiring line 12 can be suppressed by reducing corrosive substances such as sulfur which enter through the outer periphery of the Ti layer 31 along the interface between the Ti layer 31 and the insulating layer 20. This is because the entry path for corrosive substances or the like can be made longer.

### Forming TiN Layer 33

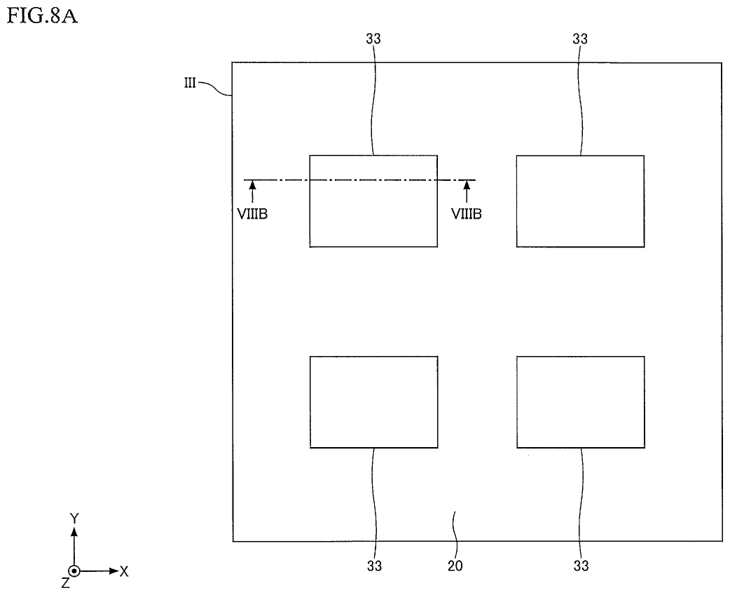

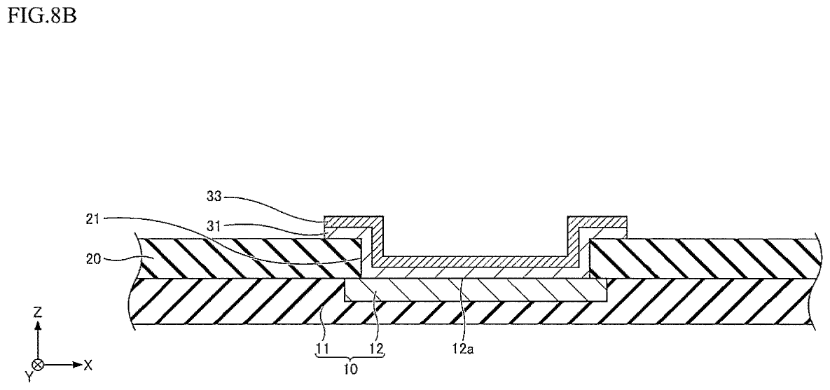

Subsequently, the TiN layer 33 is formed. With reference to FIGS. 8A and 8B, forming the TiN layer 33 is described. FIG. 8A schematically illustrates the upper surface of the region corresponding to the unit region III in the intermediate including the substrate 10, the insulating layer 20, the Ti layer 31, and the TiN layer 33. FIG. 8B schematically illustrates a cross section taken along line VIIIB-VIIIB illustrated in FIG. 8A

As illustrated in FIGS. 8A and 8B, the TiN layer 33 is formed on the Ti layer 31. The TiN layer 33 can be formed so as to cover the upper surface of the Ti layer 31 entirely or partially. However, in the case of partially covering the upper surface of the Ti layer 31, the TiN layer 33 is preferably formed so as to cover at least a region of the upper surface of the Ti layer 31 overlapping the opening 21 in a top view. Examples of the method of forming the TiN layer 33 include sputtering, vacuum deposition, the CVD, the ALD, and the like.

### Forming TiW Layer 35

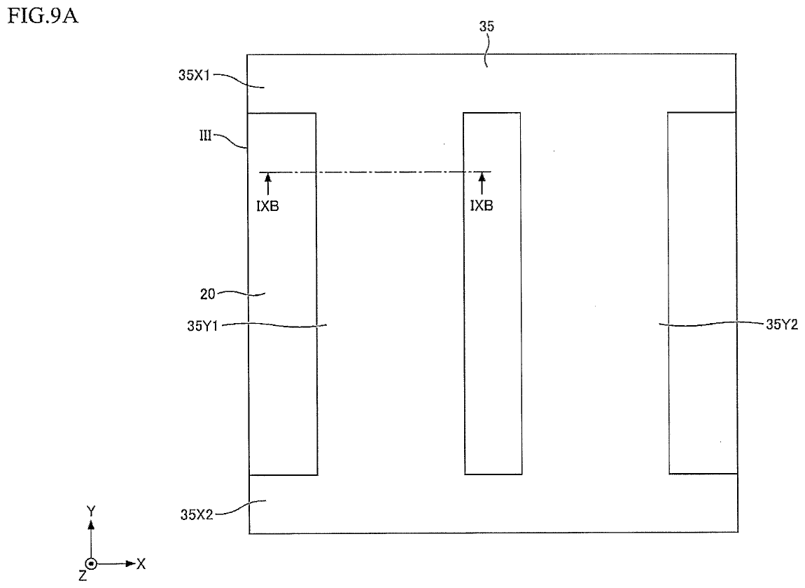

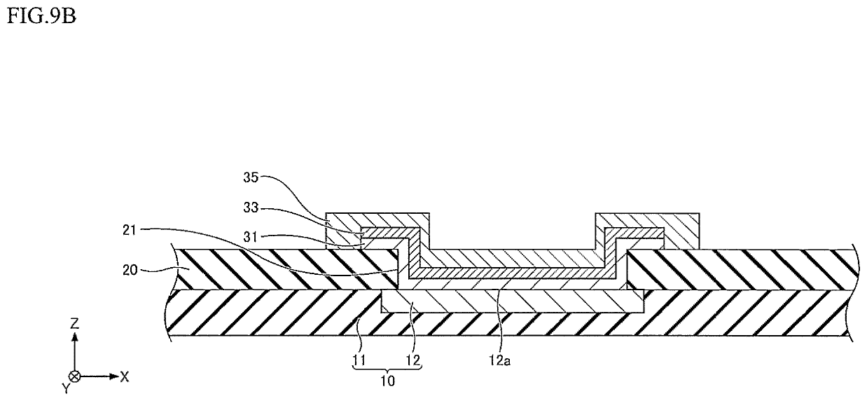

Subsequently, the TiW layer 35 is formed. Forming the TiW layer 35 is described with reference to FIGS. 9A and 9B. FIG. 9A schematically illustrates the upper surface of the region corresponding to the unit region III in the intermediate including the substrate 10, the insulating layer 20, the Ti layer 31, the TiN layer 33, and the TiW layer 35. FIG. 9B schematically illustrates a cross section taken along line IXB-IXB illustrated in FIG. 9A.

As illustrated in FIGS. 9A and 9B, the TiW layer 35 is formed over the TIN layer 33. Here, the TiW layer 35 can also function as a seed layer for plate growing the conductive member 40. Therefore, the TiW layer 35 is formed so as to correspond to a current path for plate growing the conductive member 40. For example, as illustrated in FIG. 9A, the TiW layer 35 is formed so as to include two regions 35Y1 and 35Y2 extending in the Y axis direction and two regions 35X1 and 35X2 extending in the X axis direction and intersecting with the regions 35Y1 and 35Y2, respectively. In a top view, the regions 35Y1 and 35Y2 overlap the TiN layer 33. The regions 35X1 and 35X2 are respectively connected to the regions 35X1 and 35X2 of the TiW layer 35 in the adjacent unit region III. Examples of the method of forming the TiW layer 35 include sputtering, vacuum deposition, the CVD, the ALD, and the like.

The thickness of the TiN layer 33 is smaller than that of the TiW layer 35. Since the entire surfaces of the Ti layer 31 and the TiN layer 33 are covered with the TiW layer 35, an etchant comes into contact with the TiN layer 33 subsequent to etching the TiW layer 35. This is because a process margin can be provided for the etching of the TiN layer 33.

### Forming Metal Layer 37

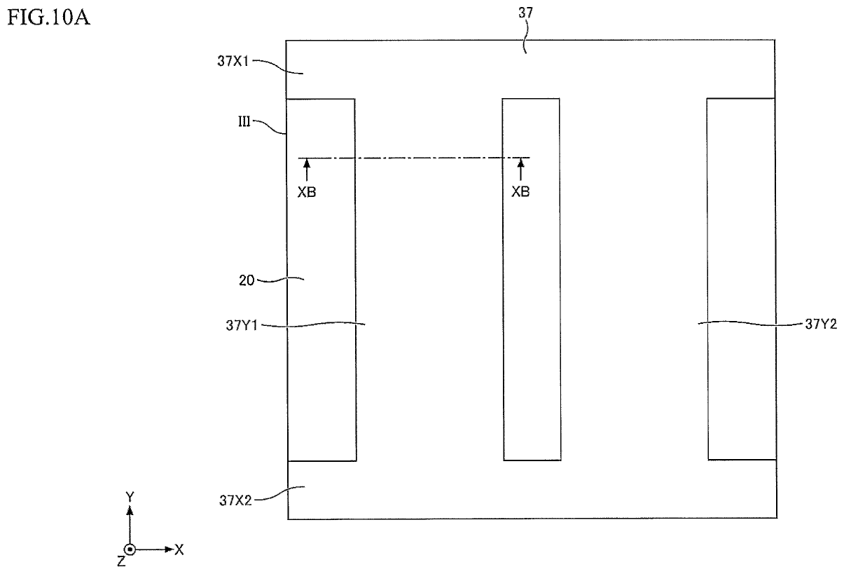

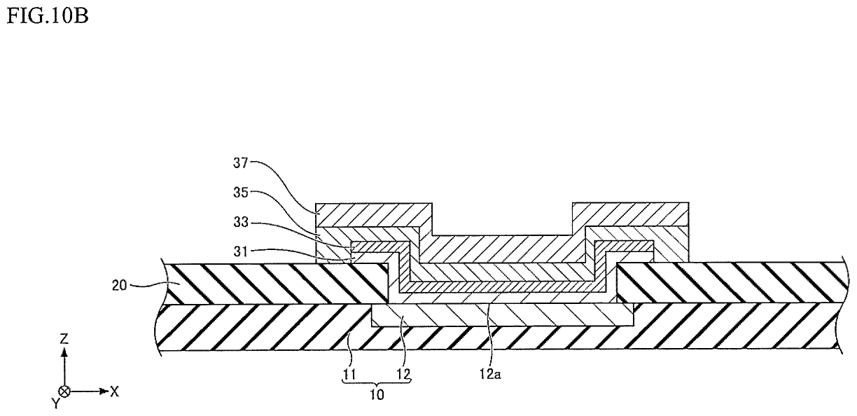

Subsequently, the metal layer 37 is formed. Forming the metal layer 37 is described with reference to FIGS. 10A and 10B. FIG. 10A schematically illustrates the upper surface of the region corresponding to the unit region III in the intermediate including the substrate 10, the insulating layer 20, the Ti layer 31, the TiN layer 33, the TiW layer 35, and the metal layer 37. FIG. 10B schematically illustrates a cross section taken along line XB-XB illustrated in FIG. 10A.

As illustrated in FIGS. 10A and 10B, the metal layer 37 is formed over the TiW layer 35. The metal layer 37 contains at least one of Au, Pt, Ru, Pd, or Rh. Similarly to the TiW layer 35, the metal layer 37 can also function as a seed layer for plate growing the conductive member 40 which will be described separately. Therefore, the metal layer 37 is preferably formed so as to overlap the TiW layer 35 in a top view. For example, as illustrated in FIG. 10A, the metal layer 37 is formed so as to include two regions 37Y1 and 37Y2 extending in the Y axis direction and two regions 37X1 and 37X2 extending in the X axis direction and intersecting with the regions 37Y1 and 37Y2, respectively. The regions 37X1 and 37X2 are connected to the regions 37X1 and 37X2 of the metal layer 37 in the adjacent unit region III, respectively. Examples of the method of forming the metal layer 37 include sputtering, vacuum deposition, the CVD, the ALD, and the like.

### Forming Resist Layer 55, Disposing Light-Emitting Element 50

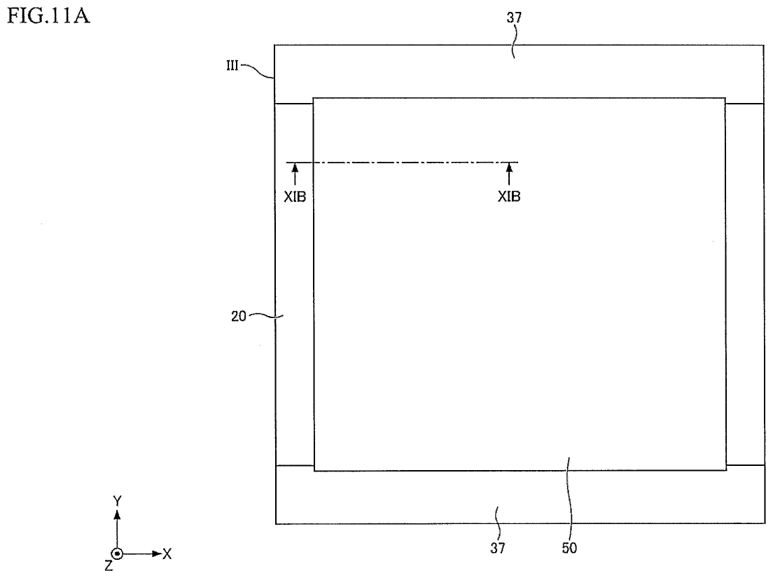

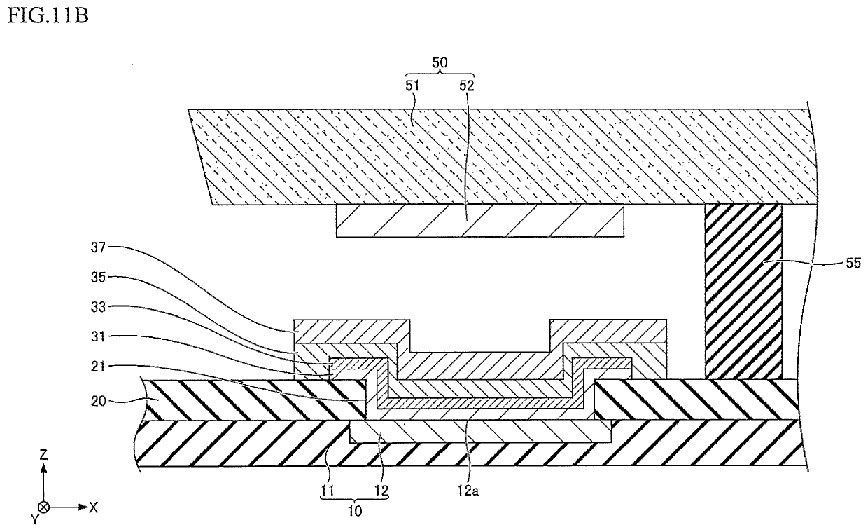

Subsequently, the resist layer 55 is formed and the light-emitting element 50 is disposed. With reference to FIGS. 11A and 11B, forming the resist layer 55 and disposing the light-emitting element 50 are described. FIG. 11A schematically illustrates the upper surface of the region corresponding to the unit region III in the intermediate including the substrate 10, the insulating layer 20, the Ti layer 31, the TiN layer 33, the TiW layer 35, the metal layer 37, and the light-emitting element 50. FIG. 11B schematically illustrates a cross section taken along line XIB-XIB illustrated in FIG. 11A.

Prior to disposing the light-emitting element 50, the resist layer 55 extending from the upper surface of the insulating layer 20 to the +Z side is formed as illustrated in FIG. 11B. Examples of the method of forming the resist layer 55 includes photolithography. However, the method of forming the resist layer 55 is not limited thereto.

Subsequent to forming the resist layer 55, the light-emitting element 50 is disposed on the metal layer 37 using a conveying means of choice. At this time, the lower surface of the semiconductor structure 51 in the light-emitting element 50 is supported on the upper surface of the resist layer 55. Accordingly, the light-emitting element 50 is disposed at a position separated from the metal layer 37. The electrode 52 disposed on the lower surface side of the light-emitting element 50 is located at a position separated from the metal layer 37 and faces the metal layer 37.

### Bonding Conductive Member 40 and Electrode 52 of Light-Emitting Element 50, Removing Resist Layer 55

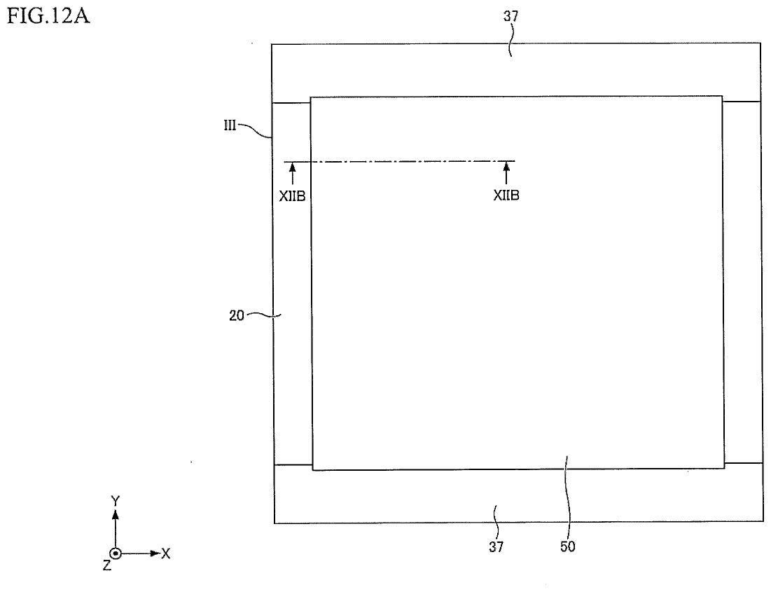

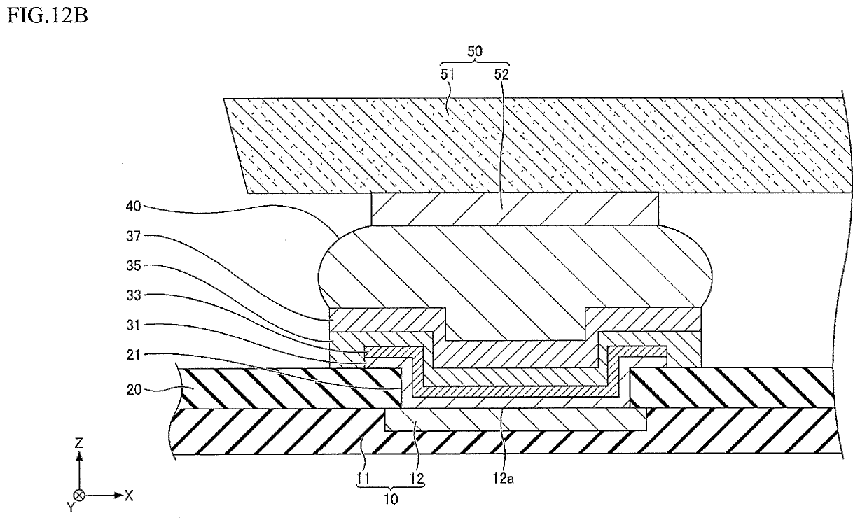

Subsequently, the conductive member 40 and the electrode 52 of the light-emitting element 50 are bonded. With reference to FIGS. 12A and 12B, bonding the conductive member 40 and the electrode 52 of the light-emitting elements 50 and removing the resist layer 55 are described. FIG. 12A schematically illustrates the upper surface of the region corresponding to the unit region III in the intermediate including the substrate 10, the insulating layer 20, the Ti layer 31, the TiN layer 33, the TiW layer 35, the metal layer 37, the light-emitting element 50, and the conductive member 40. FIG. 12B schematically illustrates a cross section taken along line XIIB-XIIB illustrated in 12A.

As illustrated in FIGS. 12A and 12B, the conductive member 40 is formed on the metal layer 37. The conductive member 40 contains Au. Examples of the method of forming the conductive member 40 include plating. For example, the conductive member 40 is formed using electrolytic plating. The conductive member 40 is plate grown using the TiW layer 35 and the metal layer 37 as seed layers.

When the conductive member 40 is formed by electrolytic plating, each of the intermediate and the metal electrode before the conductive member 40 is formed is immersed in an electrolytic plating solution. Subsequently, the outside voltage is applied to the intermediate and the metal electrode so that the TiW layer 35 and the metal layer 37 of the intermediate serve as a cathode and the metal electrode serves as an anode. Thus, the conductive member 40 extending to the +Z side is formed on the metal layer 37. That is, the upper surface of the conductive member 40 is in contact with the lower surface of the electrode 52. Thus, the conductive member 40 and the electrode 52 can be bonded. Subsequent to bonding the conductive member 40 and the electrode 52, the resist layer 55 is removed. For example, the resist layer 55 is removed using a stripper solution or the like.

### Etching at Least Part of TiW Layer 35

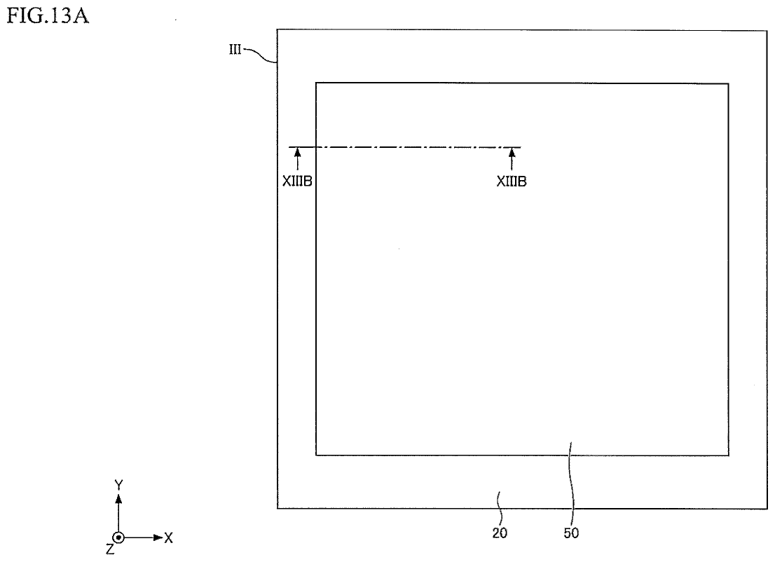

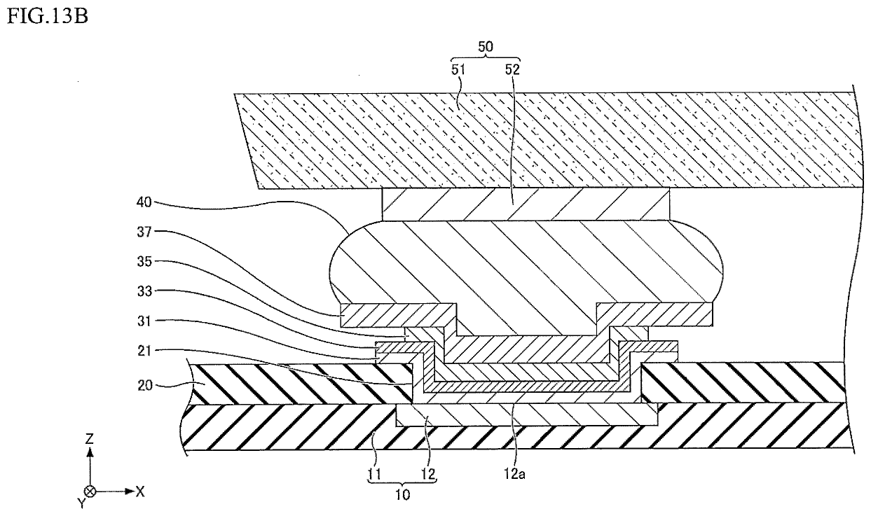

Subsequently, at least a part of the TiW layer 35 is etched. With reference to FIGS. 13A and 13B, at least a part of the TiW layer 35 is etched. FIG. 13A schematically illustrates the upper surface of the region corresponding to the unit region III in the light-emitting device 1. FIG. 13B schematically illustrates a cross section taken along line XIIIB-XIIIB illustrated in FIG. 13A.

Prior to etching at least a part of the TiW layer 35, a part of the metal layer 37 can be etched. Examples of the method of etching a part of the metal layer 37 include wet etching using an etchant that removes a material constituting the metal layer 37. Since the etching of the metal layer 37 is performed using the conductive member 40 as a mask, a part of the metal layer 37 not overlapping the conductive member 40 in a top view is removed as illustrated in FIG. 13B. In addition, a part of the region of the metal layer 37 overlapping the conductive member 40 in a top view can be removed by side etching.

Subsequent to etching a part of the metal layer 37, at least a part of the TiW layer 35 is etched. Examples of the method of etching at least a part of the TiW layer 35 include wet etching using an etchant that removes TiW layer 35. Examples of the etchant for removing the TiW layer 35 is a hydrogen peroxide-based etchant. However, the etchant for removing the TiW layer 35 is not limited thereto. Since the etching of the TiW layer 35 is performed using the conductive member 40 as a mask, a part of the TiW layer 35 not overlapping the conductive member 40 in a top view is removed as illustrated in FIG. 13B. In addition, a part of the region of the TiW layer 35 overlapping the conductive member 40 in a top view can be removed by side etching. By etching the metal layer 37 and the TiW layer 35, the plurality of the light-emitting elements 50 become electrically independent from each other.

As illustrated in FIG. 13B, the region overlapping the opening 21 in a top view on the upper surface 12a of the Cu wiring line 12 is covered with the Ti layer 31. In addition, in the example illustrated in FIG. 13B, the region of the upper surface 12a of the Cu wiring line 12 overlapping the opening 21 in a top view is further covered with the TiN layer 33. As a result, even when a part of the region of the TiW layer 35 overlapping the conductive member 40 in a top view is removed by side etching, the path connecting the outside and the Cu wiring line 12 is not formed. As a result, the possibility of the Cu wiring line 12 coming into contact with corrosive substances can be reduced. That is, the corrosion of the Cu wiring line 12 can be suppressed.

Through these steps, the light-emitting device 1 is obtained. However, the method of manufacturing the light-emitting device 1 can include other steps as appropriate. The method of manufacturing the light-emitting device 1 can include, for example, forming the light shielding member 80 between the opposing lateral surfaces of adjacent light-emitting elements 50 and between the substrate 10 and the light-emitting element 50, forming the wavelength conversion member 90 on the light-emitting element 50, disposing the wire line 70 electrically connecting the substrate 10 and the package substrate 60, forming the covering member 95 covering the wire line 70, and the like.

### Second Embodiment

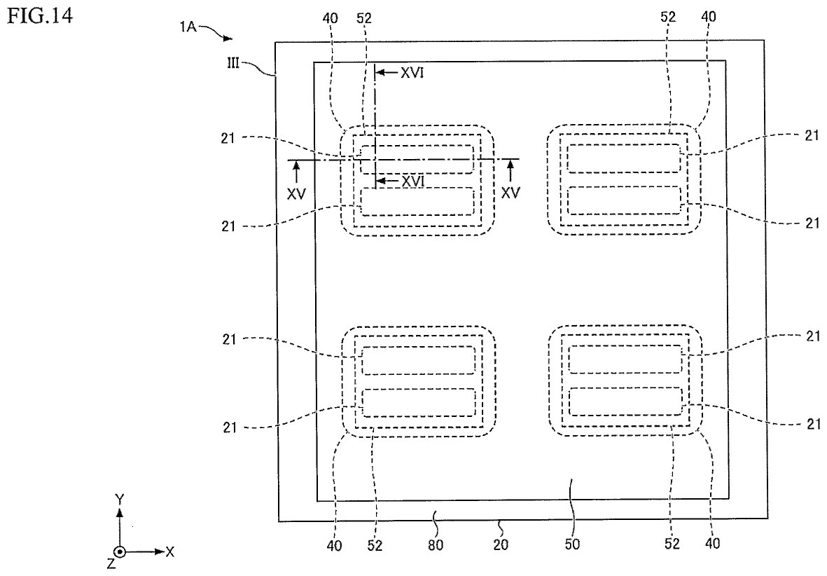

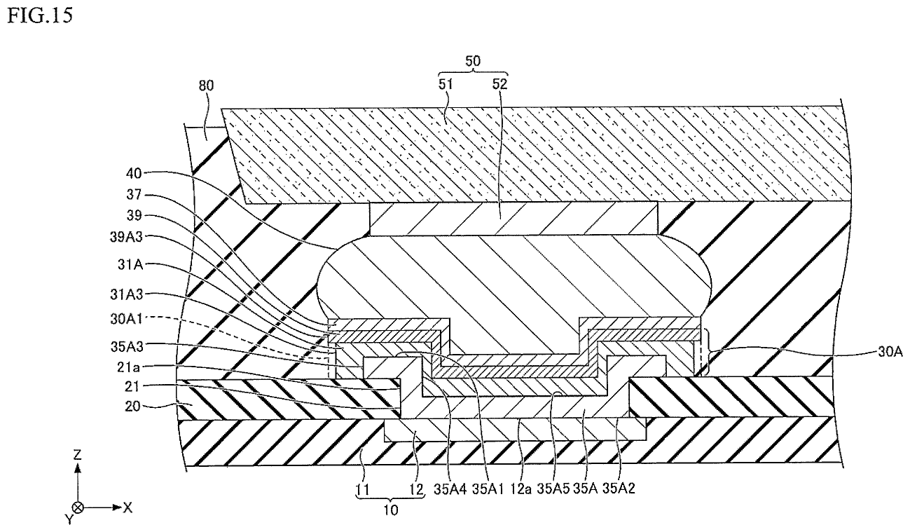

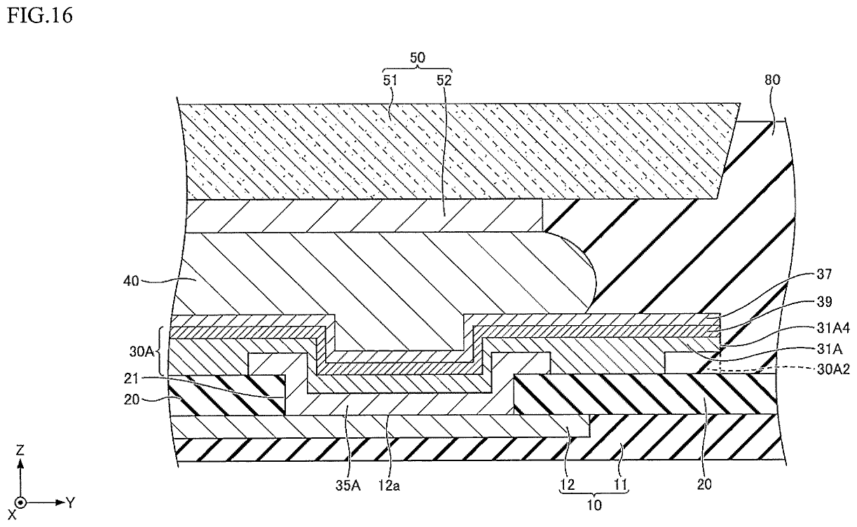

A configuration example of a light-emitting device 1A according to a second embodiment will be described with reference to FIGS. 14 to 16. FIG. 1 is a perspective view schematically illustrating the light-emitting device 1 according to the first embodiment. FIG. 14 is an enlarged schematic cross-sectional view for describing the configuration example in the unit region III of the light-emitting device 1A according to the second embodiment. FIG. 14 also illustrates, in a perspective manner, the electrode 52 of the light-emitting element 50, the opening 21 of the insulating layer 20, and the conductive member 40 surrounded by the unit region III. FIG. 15 is a cross-sectional view schematically illustrating a cross section taken along line XV-XV illustrated in FIG. 14. FIG. 16 is a cross-sectional view schematically illustrating a cross section taken along line XVI-XVI illustrated in FIG. 14. In the second embodiment, the components that are the same as those described above in the first embodiment will be denoted by the same reference numerals, and redundant descriptions thereof will be omitted as appropriate.

### Overall Configuration of Light-Emitting Device 1A

The light-emitting device 1A includes the substrate 10, the insulating layer 20, a foundation layer 30A, the metal layer 37, the conductive member 40, and the light-emitting element 50. The second embodiment differs from the first embodiment in that the foundation layer 30A is provided. The foundation layer 30A is disposed on the −Z side of the conductive member 40. The foundation layer 30A also reduces the Cu wiring line 12 of the substrate 10 coming into contact with corrosive substances. The metal layer 37 is disposed between the foundation layer 30A and the conductive member 40.

The foundation layer 30A can have a single-layer structure composed of one kind of metal or alloy, or can have a multilayer structure in which two or more kinds of layers composed of different kinds of metals or alloys are stacked. For example, the foundation layer 30A includes a TiW layer 35A and a first Ti layer 31A. In the example illustrated in FIG. 15, the foundation layer 30A further includes a Pt layer 39. However, the configuration of the foundation layer 30A is not limited thereto.

### TiW Layer 35A

The TiW layer 35A is a layer containing titanium and tungsten as main components thereof. In the TiW layer 35A, the composition ratio of titanium and tungsten is not limited. The TiW layer 35A can contain an element other than titanium and tungsten. The TiW layer 35A can function as a seed layer for growing the conductive member 40.

In the example illustrated in FIG. 15, the TiW layer 35A has an upper surface 35A1, a lower surface 35A2, an outer lateral surface 35A3, an inner lateral surface 35A4, and an inner bottom surface 35A5. The outer lateral surface 35A3 defines an outer edge of the TiW layer 35A. The outer lateral surface 35A3 is located between the upper surface 35A1 of the TiW layer 35A and the upper surface of the insulating layer 20. The inner lateral surface 35A4 of the TiW layer 35A is located between the upper surface 35A1 and the inner bottom surface 35A5.

The TiW layer 35A covers the upper surface 12a of the Cu wiring line 12. More specifically, the TiW layer 35A covers a region of the upper surface 12a of the Cu wiring line 12 overlapping the opening 21 in a top view. The TiW layer 35A also covers the inner surface 21a of the insulating layer 20 defining the opening 21. The TiW layer 35A also covers a part of the upper surface of the insulating layer 20 continuous with the inner surface 21a. This allows the TiW layer 35A to cover the region of the upper surface 12a of the Cu wiring line 12 overlapping the opening 21 in a top view. As a result, formation of the path connecting the outside and the Cu wiring line 12 can be suppressed. This reduces the possibility of the Cu wiring line 12 coming into contact with corrosive substances such as sulfur and sulfur compounds. That is, corrosion such as sulfurization of the Cu wiring line 12 can be suppressed.

### First Ti Layer 31A

The first Ti layer 31A is a layer made of titanium. The first Ti layer 31A covers each of the upper surface 35A1 and the outer lateral surface 35A3 of the TiW layer 35A. The first Ti layer 31A can cover each of the inner lateral surface 35A4 and the inner bottom surface 35A5 of the TiW layer 35A. The first Ti layer 31A at least covers each of the upper surface 35A1 and the outer lateral surface 35A3 of the TiW layer 35A, which further suppresses the formation of the path connecting the outside and the Cu wiring line 12.

As illustrated in FIG. 15, the first Ti layer 31A covers the region of the upper layer of the insulating layer 20 adjacent to the outer lateral surface 35A3 of the TiW layer 35A. The outer lateral surface 31A3 defining the outer edge of the first Ti layer 31A is located on the insulating layer 20. For example, in a top view, the outer lateral surface 31A3 of the first Ti layer 31A is located closer to the center of the first Ti layer 31A than the outer lateral surface 39A3 of the Pt layer 39 is. The outer lateral surface 31A3 of the first Ti layer 31A corresponds to the outer lateral surface of the foundation layer 30A. In other words, the foundation layer 30A includes a recessed portion 30A1 that is recessed toward the center of the foundation layer 30A in a top view from at least a part of the region of the outer lateral surface of the foundation layer 30A.

As illustrated in FIG. 16, a recessed portion 30A2 recessed toward the center of the first Ti layer 31A is also provided in the outer lateral surface 31A4 located at a position different from the position of the outer lateral surface 31A3 in the first Ti layer 31A. The outer lateral surface 31A4 of the first Ti layer 31A corresponds to another outer lateral surface of the foundation layer 30A. That is, the foundation layer 30A further includes another recessed portion 30A2 located at a position different from the position of the recessed portion 30A1.

A part of the light shielding member 80 is also located in the recessed portions 30A1 and 30A2. That is, the light shielding member 80 located in the recessed portions 30A1 and 30A2 and the +Z side region of the foundation layer 30A face each other in the Z axis direction. Therefore, even when a force acting upward on the light shielding member 80 is generated, the separation of the light shielding member 80 from the substrate 10 can be further suppressed.

### Pt Layer 39

As illustrated in FIGS. 15 and 16, the Pt layer 39 is disposed between the first Ti layer 31A and the metal layer 37. Since the foundation layer 30A includes the Pt layer 39, the corrosion of the Cu wiring line 12 can be further suppressed.

### Other

The foundation layer 30A can further include a TiN layer and a second Ti layer between the first Ti layer 31A and the Pt layer 39. The TiN layer is preferably disposed on the first Ti layer 31A. The TiN layer can further suppress the corrosion of the Cu wiring line 12. The second Ti layer is preferably disposed on the TIN layer. The second Ti layer can function as an adhesion layer between the TiN layer and the metal layer 37.

### Method of Manufacturing Light-Emitting Device 1A

Subsequently, a method of manufacturing the light-emitting device 1A according to the second embodiment is described below. The method of manufacturing the light-emitting device 1A according to the second embodiment includes preparing the substrate 10, forming the insulating layer 20, forming the first TiW layer and the second TiW layer, forming the first Ti layer 31A, forming the metal layer 37, forming the resist layer 55, disposing the light-emitting element 50, bonding the conductive member 40 and the electrode 52 of the light-emitting element 50, removing the resist layer 55, and etching the second TiW layer. For convenience of description, the method of manufacturing the light-emitting device 1A according to the second embodiment is described using an example form in the region corresponding to a particular unit region III, but the same applies to other unit regions III.

The preparing of the substrate 10, the forming of the insulating layer 20, the forming of the metal layer 37, the forming of the resist layer 55, the disposing of the light-emitting element 50, the bonding of the conductive member 40 and the electrode 52 of the light-emitting element 50, and the removing of the resist layer 55 are the same as or similar to those in the first embodiment, and thus description thereof will be omitted.

### Forming First TiW Layer and Second TiW Layer

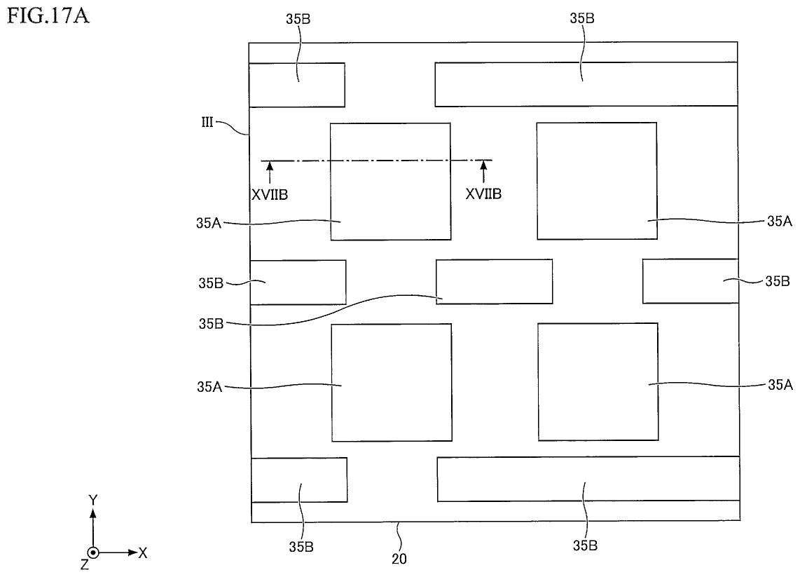

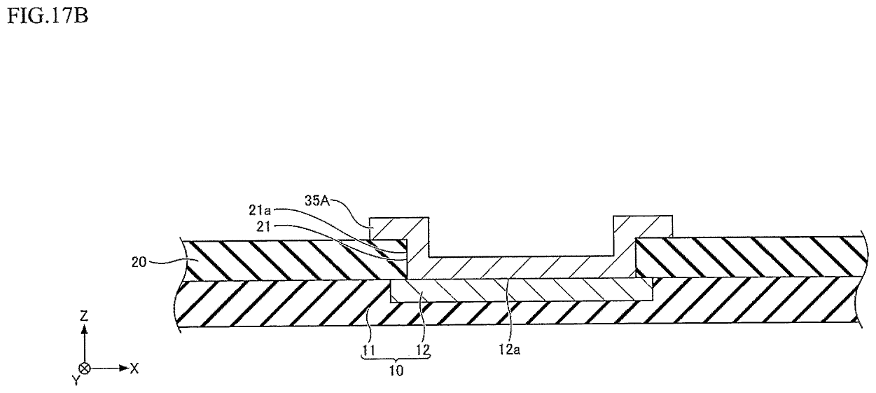

Subsequent to forming the insulating layer 20, the first TiW layer and the second TiW layer are formed. With reference to FIGS. 17A and 17B, forming the first TiW layer and the second TiW layer is described. The fist TiW layer corresponds to the TiW layer 35A described with reference to FIGS. 15 and 16. Hereinafter, the first TiW layer will be referred to as the “first TiW layer 35A”. The second TiW layer will be referred to as the “second TiW layer 35B”. FIG. 17A schematically illustrates the upper surface of the region corresponding to the unit region III in the intermediate including the substrate 10, the insulating layer 20, the first TiW layer 35A, and the second TiW layer 35B. FIG. 17B schematically illustrates a cross section taken along line XVIIB-XVIIB illustrated in FIG. 17A.

As illustrated in FIGS. 17A and 17B, the second TiW layer 35A is formed so as to cover the upper surface 12a of the Cu wiring line 12. That is, a region of the upper surface 12a of the Cu wiring line 12 overlapping the opening 21 in a top view is covered with the first TiW layer 35A. Thus, the upper surface 12a of the Cu wiring line 12 is covered with the insulating layer 20 or the first TiW layer 35A. The first TiW layer 35A is formed so as to cover the inner surface 21a of the insulating layer 20 defining the opening 21. In addition, the first TiW layer 35 is formed to cover a part of the upper surface of the insulating layer 20 continuous with the inner surface 21a. The method of forming the first TiW layer 35A can be the same as the method for forming the TiW layer 35 of the first embodiment.

The second TiW layer 35B is formed at a timing the same as or different from the timing of forming the first TiW layer 35A. As illustrated in FIG. 17A, the second TiW layer 35B is formed on the upper surface of the insulating layer 20 at a position separated from the first TiW layer 35A. In the example illustrated in FIG. 17A, seven second TiW layers 35B are formed, but the number of the second TiW layers 35B is not limited thereto. The second TiW layers 35B are respectively formed at positions separated from each other on the upper surface of the insulating layer 20. The method of forming the second TiW layer 35B can be the same as the method for forming the TiW layer 35 of the first embodiment.

### Forming First Ti Layer 31A

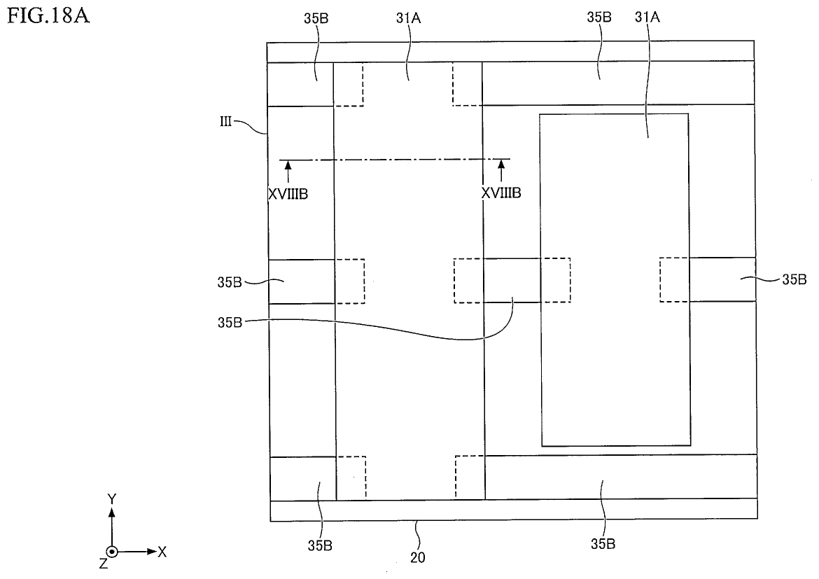

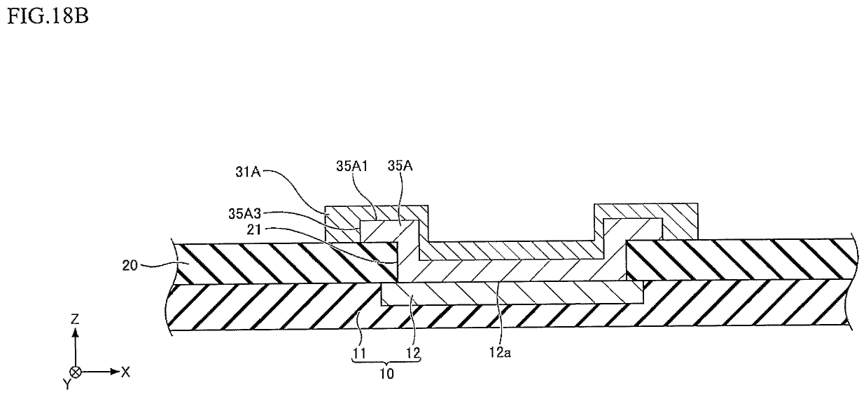

Subsequently, the first Ti layer 31A is formed. With reference to FIGS. 18A and 18B, forming the first Ti layer 31A is described. FIG. 18A schematically illustrates the upper surface of the region corresponding to the unit region III in the intermediate including the substrate 10, the insulating layer 20, the first TiW layer 35A, the second TiW layer 35B, and the first Ti layer 31A. FIG. 18B schematically illustrates a cross section taken along line XVIIIB-XVIIIB illustrated in FIG. 18A.

As illustrated in FIGS. 18A and 18B, the first TiW layer 31A is formed so as to cover the upper surface 35A1 of the first TiW layer 35A and the outer lateral surface 35A3 of the first TiW layer 35A located between the upper surface 35A1 of the first TiW layer 35A and the upper surface of the insulating layer 20 (see FIG. 18B). The first Ti layer 31A is formed so as to cover a part of the second TiW layer 35B (see FIG. 18A). The second TiW layer 35B has a region overlapping the first Ti layer 31A and a region not overlapping the first Ti layer 31A in a top view.

In forming the metal layer 37 subsequent to forming the first Ti layer 31A, the metal layer 37 is formed on the first Ti layer 31A. The second TiW layer 35B has a region overlapping the metal layer 37 and a region not overlapping the metal layer 37 in a top view. As a result, a current path is formed for plate growing the conductive member 40, including the first Ti layer 31A, the first TiW layer 35A, the second TiW layer 35B, and the metal layer 37. The method of forming the first Ti layer 31A can be the same as the method for forming the Ti layer 31 of the first embodiment. The Pt layer 39 can be formed between forming the first Ti layer 31A and forming the metal layer 37. Thus, the Pt layer 39 is disposed between the first Ti layer 31A and the metal layer 37.

### Etching Second TiW Layer 35B

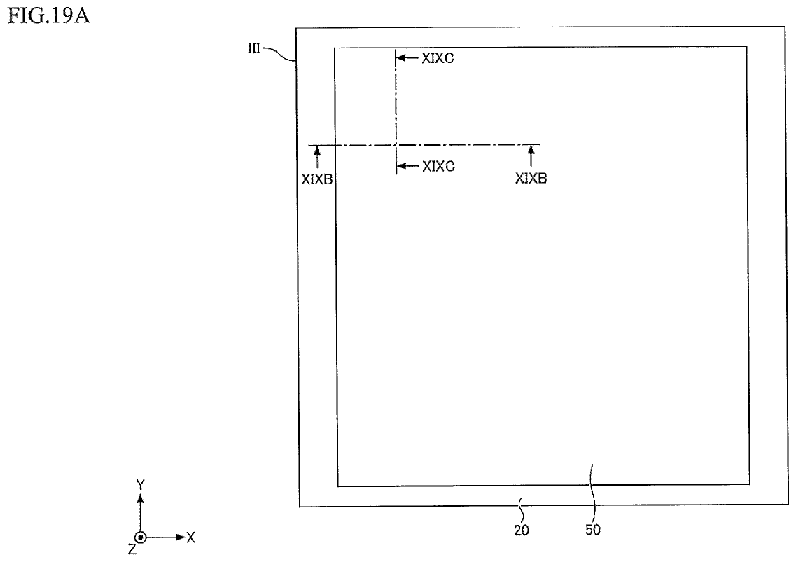

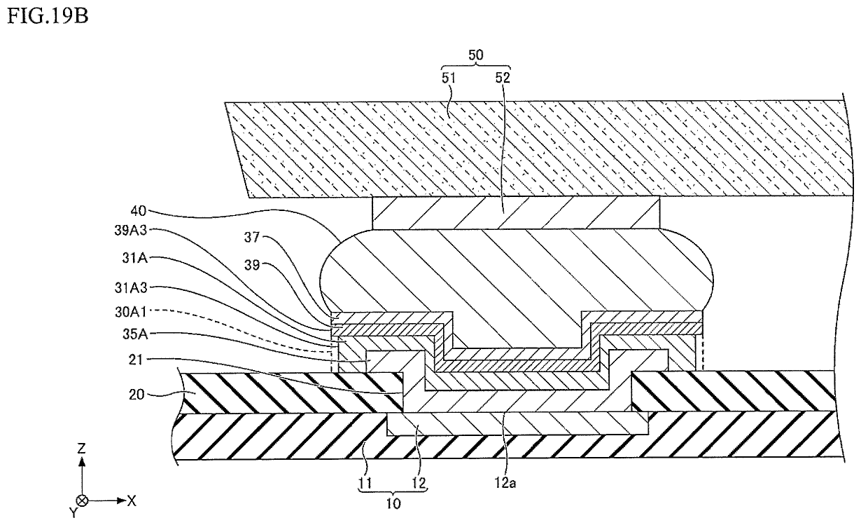

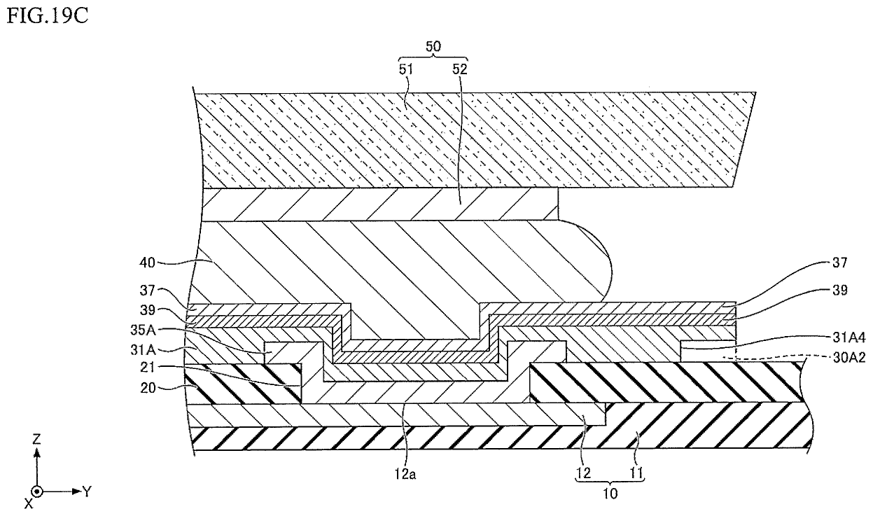

Subsequently, the second TiW layer 35B is etched. With reference to FIGS. 19A to 19C, etching the second TiW layer 35B is described. FIG. 19A schematically illustrates the upper surface of the region corresponding to the unit region III in the light-emitting device 1A. FIG. 19B schematically illustrates a cross section taken along line XIXB-XIXB illustrated in FIG. 19A. FIG. 19C schematically illustrates a cross section taken along line XIXC-XIXC illustrated in FIG. 19A.

The second TiW layer 35B is etched by wet etching using a predetermined etchant. At this time, as illustrated in FIGS. 19A and 19B, the first TiW layer 35A is located at a position separated from the second TiW layer 35B and is covered with the first Ti layer 31A. Therefore, when the second TiW layer 35B is etched, the etchant does not reach the first TiW layer 35A. Thus, the second TiW layer 35B can be removed, while leaving the first TiW layer 35A covering the Cu wiring line 12. In other words, this suppresses the formation of the path continuous with the outside and the Cu wiring line 12, while making each of the plurality of light-emitting elements 50 be electrically independent. The etchant for etching the second TiW layer 35B can be the same as or similar to the etchant used for etching a part of the TiW layer 35 in the first embodiment.

The etchant for etching the second TiW layer 35B can slightly remove the first Ti layer 31A. Therefore, when the second TiW layer 35B is etched, the outer lateral surface 31A3 of the first Ti layer 31A is slightly removed. As a result, as illustrated in FIG. 19B, the outer lateral surface 31A3 of the first Ti layer 31A is located closer to the center of the first Ti layer 31A than the outer lateral surface 39A3 of the Pt layer 39 is, for example. The region of the first Ti layer 31A removed with the etchant for etching the second TiW layer 35B corresponds to the recessed portion 30A1 of the foundation layer 30A described with reference to FIG. 15.

As the second TiW layer 35B is etched, the area of the second TiW layer 35B overlapping the first Ti layer 31A in a top view is also removed. That is, before etching, a region in which the second TiW layer 35B and the first Ti layer 31A overlap each other in a top view becomes a cavity by etching the second TiW layer 35B. For example, in the example illustrated in FIG. 19C, a cavity recessed toward the center of the first Ti layer 31A is formed in the outer lateral surface 31A4 of the first Ti layer 31A. This cavity corresponds to the recessed portion 30A2 of the foundation layer 30A described with reference to FIG. 16.

In disposing the light shielding member 80 subsequent to forming the second TiW layer 35B, a part of the light shielding member 80 is also located in the recessed portions 30A1 and 30A2. Accordingly, the light shielding member 80 located in the recessed portions 30A1 and 30A2 and the +Z side region of the foundation layer 30A face each other in the Z axis direction. As a result, even when a force acting upward on the light shielding member 80 is generated, the separation of the light shielding member 80 from the substrate 10 can be suppressed.

Through these steps, the light-emitting device 1A is obtained. The method of manufacturing the light-emitting device 1A can further include other steps. In the method of manufacturing the light-emitting device 1A, the “forming of the first TiW layer 35A and the second TiW layer 35B” is replaced with the “forming of the first foundation layer and the second foundation layer”. The “etching of the second TiW layer 35B” can be replaced with the “etching the second foundation layer”.

The first foundation layer corresponds to a layer including the first TiW layer 35A. The second foundation layer corresponds to a layer including the second TiW layer 35B. However, the first foundation layer is not limited to the configuration including the first TiW layer 35A. The second foundation layer is not limited to the configuration including the second TiW layer 35B.

Although the preferred embodiments and the like have been described in detail above, the disclosure is not limited to the above-described embodiments and the like, various modifications and substitutions can be made to the above-described embodiments and the like without departing from the scope described in the claims.

1. A light-emitting device, comprising:
a substrate comprising a base material and a Cu wiring line disposed on an upper surface side of the base material;
an insulating layer disposed on the substrate and having an opening on at least a part of an upper surface of the Cu wiring line;
a Ti layer covering at least the upper surface of the Cu wiring line;
a TiN layer disposed on the Ti layer;
a TiW layer disposed on the TiN layer;
a metal layer disposed on the TiW layer and containing at least one of Au, Pt, Ru, Pd, or Rh;
a conductive member disposed on the metal layer and containing Au; and
a light-emitting element comprising an electrode disposed on the conductive member.

2. The light-emitting device according to claim 1, wherein a thickness of the TiW layer is smaller than a thickness of the metal layer.

3. The light-emitting device according to claim 1, wherein a thickness of the TiN layer is smaller than the thickness of the TiW layer.

4. The light-emitting device according to claim 1, wherein, in a top view, an outer edge of the TiW layer is located closer to a center of the metal layer than an outer edge of the metal layer is to the center of the metal layer.

5. A light-emitting device, comprising:
a substrate comprising a base material and a Cu wiring line disposed on an upper surface side of the base material;
an insulating layer disposed on the substrate and having an opening on at least a part of an upper surface of the Cu wiring line;
a TiW layer covering the upper surface of the Cu wiring line, an inner surface of the insulating layer defining the opening, and a part of an upper surface of the insulating layer continuous with the inner surface;
a first Ti layer covering an upper surface of the TiW layer, and covering an outer lateral surface of the TiW layer located between the upper surface of the TiW layer and the upper surface of the insulating layer;
a metal layer disposed on the first Ti layer and containing at least one of Au, Pt, Ru, Pd, or Rh;
a conductive member disposed on the metal layer and containing Au; and
a light-emitting element comprising an electrode disposed on the conductive member.

6. The light-emitting device according to claim 5, further comprising:
a Pt layer disposed between the first Ti layer and the metal layer,
wherein the metal layer is made of Au.

7. The light-emitting device according to claim 5, further comprising:
a TiN layer disposed on the first Ti layer; and
a second Ti layer disposed on the TiN layer.

8. A light-emitting device, comprising:
a substrate comprising a base material and a Cu wiring line disposed on an upper surface side of the base material;
an insulating layer disposed on the substrate and having an opening on at least a part of an upper surface of the Cu wiring line;
a foundation layer covering the upper surface of the Cu wiring line, an inner surface of the insulating layer defining the opening, and a part of an upper surface of the insulating layer continuous with the inner surface;
a metal layer disposed on the foundation layer and containing at least one of Au, Pt, Ru, Pd, or Rh;
a conductive member disposed on the metal layer and containing Au; and
a light-emitting element comprising an electrode disposed on the conductive member,
wherein, in the foundation layer, a portion covering a part of the upper surface of the insulating layer comprises an outer lateral surface defining an outer edge of the foundation layer, and a recessed portion recessed toward a center of the foundation layer in a top view from at least a part of a region of the outer lateral surface.

9. A method of manufacturing a light-emitting device, comprising:
preparing a substrate comprising a base material and a Cu wiring line disposed on an upper surface side of the base material;
forming an insulating layer on the substrate so that an opening is formed on at least a part of an upper surface of the Cu wiring line;
forming a Ti layer so as to cover at least the upper surface of the Cu wiring line;
forming a TiN layer on the Ti layer;
forming a TiW layer on the TiN layer;
forming a metal layer on the TiW layer, the metal layer containing at least one of Au, Pt, Ru, Pd, or Rh;
forming a resist layer on at least a part of the insulating layer;
disposing a light-emitting element on the resist layer at a position separated from the metal layer;
forming a conductive member containing Au on the metal layer by plating and bonding the conductive member and an electrode of the light-emitting element;
removing the resist layer; and
etching at least a part of the TiW layer that does not overlap the conductive member in a top view.

10. A method of manufacturing a light-emitting device, the method comprising:
preparing a substrate comprising a base material and a Cu wiring line disposed on an upper surface side of the base material;
forming an insulating layer on the substrate so that an opening is formed on at least a part of an upper surface of the Cu wiring line;
forming a first TiW layer and a second TiW layer, the first TiW layer being formed to cover each of the upper surface of the Cu wiring line, an inner surface of the insulating layer defining the opening, and a part of the upper surface of the insulating layer continuous with the inner surface, and the second TiW layer being formed on the upper surface of the insulating layer at a position separated from the first TiW layer;
forming a first Ti layer so as to cover an upper surface of the first TiW layer and an outer lateral surface of the first TiW layer located between the upper surface of the first TiW layer and the upper surface of the insulating layer;
forming a metal layer on the first Ti layer, the metal layer containing at least one of Au, Pt, Ru, Pd, or Rh;
forming a resist layer on at least a part of the insulating layer;
disposing a light-emitting element on the resist layer at a position separated from the metal layer;
forming a conductive member containing Au on the metal layer by plating and bonding the conductive member and an electrode of the light-emitting element;
removing the resist layer; and
etching the second TiW layer.

11. A method of manufacturing a light-emitting device, the method comprising:
preparing a substrate comprising a base material and a Cu wiring line disposed on an upper surface side of the base material;
forming an insulating layer on the substrate so that an opening is formed on at least a part of an upper surface of the Cu wiring line;
forming a first foundation layer and a second foundation layer, the first foundation layer being formed to cover each of the upper surface of the Cu wiring line, an inner surface of the insulating layer defining the opening, and a part of the upper surface of the insulating layer continuous with the inner surface, and the second foundation layer being formed on the upper surface of the insulating layer at a position separated from the first foundation layer;
forming a metal layer on at least the first foundation layer, the metal layer containing at least one of Au, Pt, Ru, Pd, or Rh;
forming a resist layer on at least a part of the insulating layer, disposing a light-emitting element on the resist layer at a position separated from the metal layer;
forming a conductive member containing Au on the metal layer by plating and bonding the conductive member and an electrode of the light-emitting element;
removing the resist layer; and
etching the second foundation layer.
